(19) United States
(12) Patent Application Publication
(10) Pub. No.: US 2024/0313707 A1
(43) Pub. Date: Sep. 19, 2024

(54) TRACKER MODULE, POWER SUPPLY SYSTEM, RADIO FREQUENCY SYSTEM, COMMUNICATION DEVICE, AND IC CHIP

(71) Applicant: Murata Manufacturing Co., Ltd., Nagaokakyo-shi (JP)

(72) Inventors: Sho OKAMOTO, Nagaokakyo-shi (JP); Muneharu KATO, Nagaokakyo-shi (JP); Kouji YAMAGUCHI, Nagaokakyo-shi (JP)

(21) Appl. No.: 18/602,329

(22) Filed: Mar. 12, 2024

(30) Foreign Application Priority Data
Mar. 17, 2023 (JP) 2023-043564

(51) Int. Cl. H03F 1/02; H03F 3/24

(52) U.S. Cl. CPC H03F 1/0238; H03F 3/245; H03F 2200/105; H03F 2200/451

(57) ABSTRACT

A tracker module is provided that includes a board, an IC chip, and at least one capacitor included in a switched-capacitor circuit. The IC chip is disposed at the board. The switched-capacitor circuit is configured to generate a plurality of discrete voltages based on an input voltage. The IC chip includes at least one switch included in a switched-capacitor circuit and at least one switch included in a supply modulator. The supply modulator selectively outputs at least one of the plurality of discrete voltages to a power amplifier. The at least one capacitor is stacked on the IC chip.

### CROSS REFERENCE TO RELATED APPLICATIONS

This application claims priority to Japanese Patent Application No. 2023-043564, filed Mar. 17, 2023, the entire content of which is hereby incorporated by reference in its entirety.

### TECHNICAL FIELD

The present disclosure relates to a tracker module, a power supply system, a radio frequency system, a communication device, and an IC chip, and more specifically, a tracker module including a capacitor, a power supply system and a radio frequency system including the tracker module, a communication device including the radio frequency system, and an IC chip used in the tracker module.

### BACKGROUND

U.S. Pat. No. 8,829,993 discloses a power supply modulation circuit capable of supplying, to a power amplifier, a power supply voltage that is dynamically adjusted with time in accordance with a radio frequency (RF) signal. The power supply modulation circuit is configured to output one of a plurality of discrete voltages to the power amplifier. The plurality of discrete voltages is generated by using, for example, a switched-capacitor circuit.

When the power supply modulation circuit in U.S. Pat. No. 8,829,993 is provided as a tracker module, the tracker module may increase in size. Depending on a disposition method of capacitors, output characteristics may deteriorate due to resistance and parasitic capacitance in a wiring portion of the switched-capacitor circuit.

### SUMMARY OF THE INVENTION

Accordingly, it is an object of the present disclosure to provide a tracker module, a power supply system, a radio frequency system, a communication device, and an IC chip that reduces deterioration in output characteristics and also reduces an overall size of the apparatus.

A tracker module according to an exemplary aspect includes a board, an IC chip, and at least one capacitor included in a switched-capacitor circuit. The IC chip is disposed at the board. The switched-capacitor circuit is configured to generate a plurality of discrete voltages based on an input voltage. The IC chip includes at least one switch included in the switched-capacitor circuit and at least one switch included in a supply modulator. The supply modulator is configured to selectively output at least one of the plurality of discrete voltages to a power amplifier. The at least one capacitor is stacked on the IC chip.

A tracker module according to another aspect of the present disclosure includes a board, an IC chip, and at least one capacitor included in a switched-capacitor circuit. The IC chip is disposed between the at least one capacitor and the board. The switched-capacitor circuit is configured to generate a plurality of discrete voltages based on an input voltage. The IC chip includes at least one switch included in the switched-capacitor circuit and at least one switch included in a supply modulator. The supply modulator is configured to selectively output at least one of the plurality of discrete voltages to a power amplifier.

A power supply system according to another exemplary aspect of the present disclosure includes the tracker module, a power inductor, and a second (or additional) board. The power inductor is used in a pre-regulator circuit. The pre-regulator circuit is configured to convert a DC voltage into the input voltage. The tracker module and the power inductor are disposed at the second board. A height of the power inductor from the second board is greater than a height of the tracker module from the second board.

A radio frequency system according to an exemplary aspect of the present disclosure includes the tracker module and a power amplifier connected to the tracker module.

A communication device according to an exemplary aspect of the present disclosure includes the radio frequency system, and a signal processing circuit connected to the radio frequency system.

An IC chip according to an exemplary aspect of the present disclosure is connected to at least one capacitor included in a switched-capacitor circuit. The switched-capacitor circuit is configured to generate a plurality of discrete voltages based on an input voltage. The IC chip includes at least one switch included in the switched-capacitor circuit and at least one switch included in a supply modulator. The supply modulator is configured to selectively output at least one of the plurality of discrete voltages to a power amplifier. The at least one capacitor is stacked on the IC chip.

According to the tracker module, the power supply system, the radio frequency system, the communication device, and the IC chip according to the above aspects, deterioration in output characteristics can be reduced and the size of the tracker module can also be reduced.

### BRIEF DESCRIPTION OF THE DRAWINGS

FIG. 1 is a plan view of a tracker module according to Embodiment 1;

FIG. 2 is a plan view of an IC chip in the tracker module according to Embodiment 1;

FIG. 3 is a conceptual diagram of the tracker module according to Embodiment 1;

FIG. 4 illustrates the tracker module according to Embodiment 1, and is a cross-sectional view taken along line III-III in FIG. 1;

FIG. 5 is a circuit block diagram of a power supply circuit, a radio frequency system, and a communication device according to Embodiment 1;

FIG. 6A is a waveform diagram illustrating an example of transition of a power supply voltage in a digital ET mode;

FIG. 6B is a waveform diagram illustrating an example of transition of the power supply voltage in an analog ET mode;

FIG. 7 is a circuit diagram of the power supply circuit according to Embodiment 1;

FIG. 8 is a circuit configuration diagram of a digital control circuit in the power supply circuit according to Embodiment 1;

FIG. 9 is a cross-sectional view of a tracker module according to Embodiment 2;

FIG. 10 is a cross-sectional view of a tracker module according to Embodiment 3;

FIG. 11 is a cross-sectional view of a tracker module according to Embodiment 4;

FIG. 12 is a plan view of a power supply system according to Embodiment 5; and

FIG. 13 illustrates the power supply system according to Embodiment 5, and is a cross-sectional view taken along line X-X in FIG. 12.

### DETAILED DESCRIPTION

Hereinafter, Exemplary Embodiments 1 to 5 will be described with reference to the drawings. The drawings referred to in the following embodiments or the like are schematic drawings. The size and thickness of the component in the drawings do not necessarily reflect actual dimensions, and the ratio of the sizes and the ratio of the thicknesses between the components do not necessarily reflect the actual dimensional ratios.

### Exemplary Embodiment 1

### (1) Tracker Module

A tracker module 100 according to Embodiment 1 will be described with reference to the drawings.

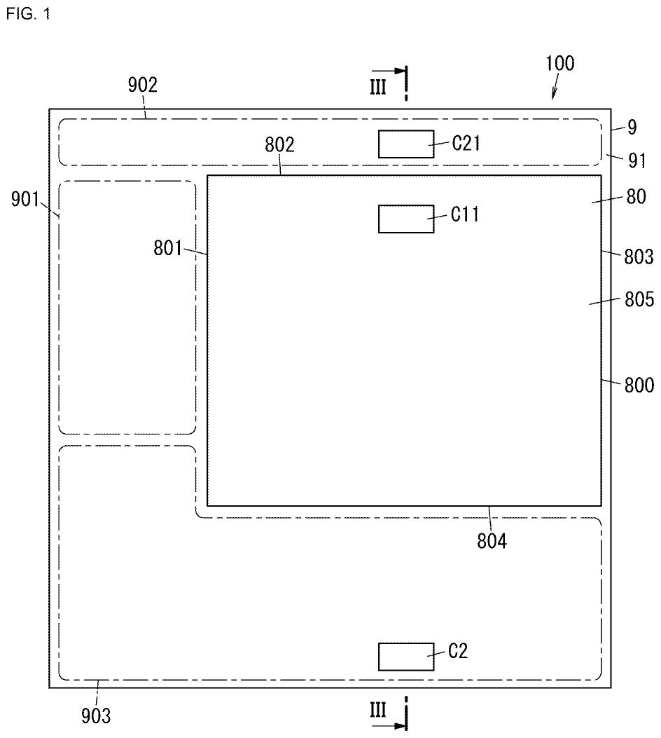

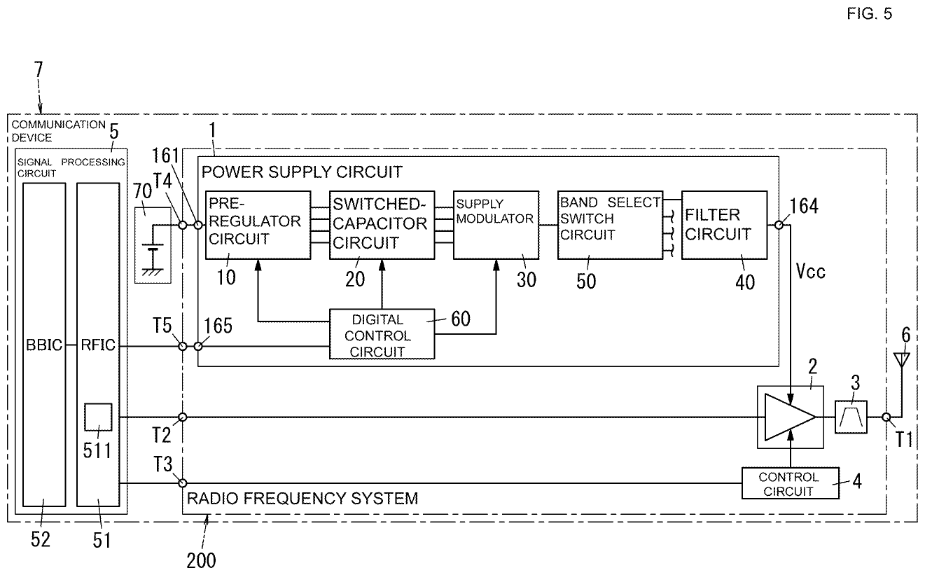

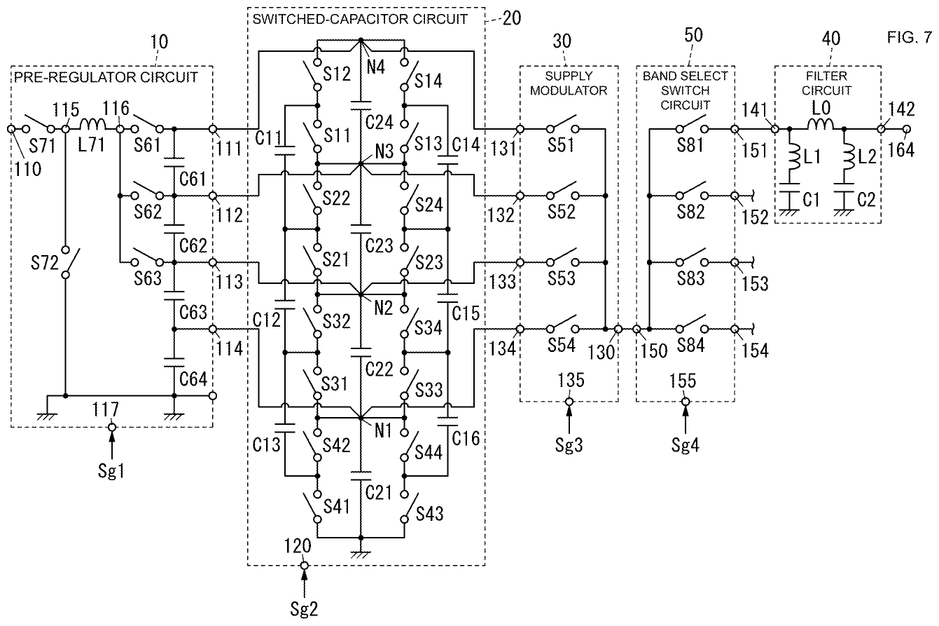

As shown, the tracker module 100 according to Embodiment 1 includes a module laminate 9, an IC chip 80, and a filter circuit 40 (see FIGS. 5 and 7), as illustrated in FIGS. 1 to 4. The IC chip 80 is disposed at the module laminate 9. The filter circuit 40 includes a plurality of functional elements (a plurality of inductors L0, L1, and L2 and a plurality of capacitors C1 and C2 in FIG. 7). The IC chip 80 includes at least one switch included in a switched-capacitor circuit 20 (see FIG. 7) and at least one switch included in a supply modulator 30 (see FIGS. 3 and 7). In operation, the switched-capacitor circuit 20 is configured to generate a plurality of discrete voltages based on an input voltage. The supply modulator 30 is configured to selectively output at least one of the plurality of discrete voltages to the filter circuit 40. The plurality of functional elements of the filter circuit 40 include at least one functional element integrated on the IC chip 80. For example, as illustrated in FIG. 5, the tracker module 100 is configured to be connected to a direct current (DC) power source 70 provided in a communication device 7 and to supply a power supply voltage Vcc to a power amplifier 2 provided in the communication device 7.

### (2) Circuit Configurations of Power Supply Circuit, Radio Frequency System, and Communication Device

Circuit configurations of a power supply circuit 1, a radio frequency system 200, and the communication device 7 according to Embodiment 1 will be described with reference to the drawings.

### (2.1) Circuit Configuration of Radio Frequency System

As illustrated in FIG. 5, the radio frequency system 200 includes a power supply circuit 1, a power amplifier 2, a filter 3, a control circuit 4, and a plurality of external connection terminals. The plurality of external connection terminals includes an antenna terminal T1, a signal input terminal T2, a first control terminal T3, a power source connection terminal T4, and four (only one is illustrated in FIG. 5) second control terminals T5.

The power supply circuit 1 is a circuit that is configured to supply, to the power amplifier 2, a power supply voltage Vcc having a voltage level selected from a plurality of discrete voltage levels based on an envelope signal.

In the communication device 7 including the power supply circuit 1 and the power amplifier 2, an envelope tracking method (referred to as an “ET method” below) can be used when the power amplifier 2 amplifies a radio frequency signal. The ET method includes an analog envelope tracking method (referred to as an “analog ET method” below) and a digital envelope tracking method (referred to as a “digital ET method” below).

The digital ET method is a method of tracking an envelope of a radio frequency signal (e.g., a modulated signal) by using a plurality of discrete voltages having different voltage levels within one frame. A mode in which the digital ET method is applied to generate the power supply voltage Vcc is referred to as a digital ET mode. The analog ET method is a method of tracking an envelope of a radio frequency signal by using a continuous voltage level. A mode in which the analog ET method is applied to generate the power supply voltage Vcc is referred to as an analog ET mode.

For purposes of this disclosure, a frame represents a unit forming a radio frequency signal. For example, in 5th Generation New Radio (5G NR) and Long Term Evolution (LTE) (registered trademark), a frame includes 10 subframes, each subframe includes a plurality of slots, and each slot includes a plurality of symbols. The subframe length is 1 ms, and the frame length is 10 ms.

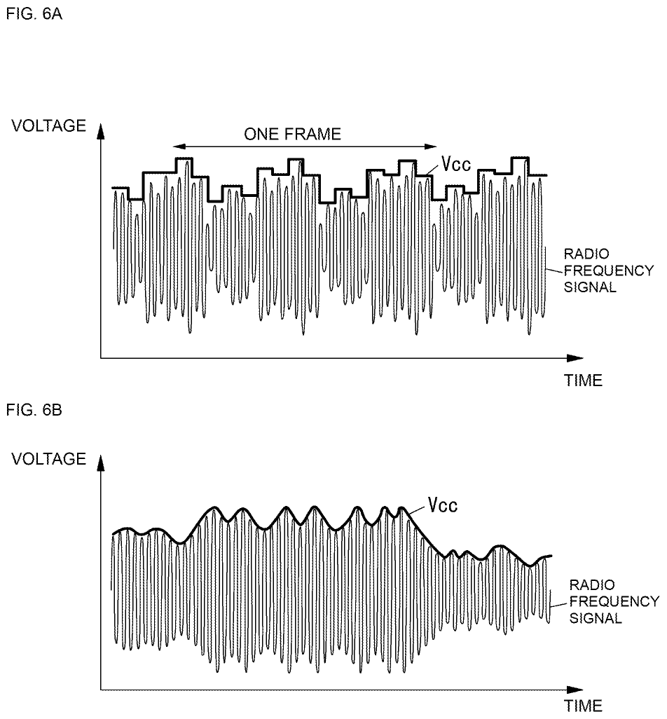

Here, the digital ET mode and the analog ET mode will be described with reference to FIGS. 6A and 6B.

In the digital ET mode, as illustrated in FIG. 6A, the envelope of the radio frequency signal is tracked by causing the power supply voltage Vcc to fluctuate to a plurality of discrete voltage levels within one frame. As a result, the waveform of the power supply voltage Vcc becomes a rectangular waveform. In the digital ET mode, the power supply voltage level is selected from the plurality of discrete voltage levels based on the envelope signal.

In the analog ET mode, as illustrated in FIG. 6B, the envelope of the radio frequency signal is tracked by causing the power supply voltage Vcc to continuously fluctuate. In the analog ET mode, the power supply voltage Vcc is determined based on the envelope signal. In the analog ET mode, when a channel bandwidth is narrow (in a case where the channel bandwidth is less than 60 MHz, for example), the power supply voltage Vcc easily follows the change in the envelope of the radio frequency signal, but when the channel bandwidth is wide (in a case where the channel bandwidth is equal to or more than, for example, 60 MHz), the power supply voltage Vcc has difficulty in following the change in the envelope of the radio frequency signal. In other words, when the channel bandwidth is wide, the amplitude change of the power supply voltage Vcc is likely to be delayed with respect to the change in the envelope of the radio frequency signal.

On the other hand, when the channel bandwidth is wide, the tracking ability of the power supply voltage Vcc to the radio frequency signal can be improved by applying the digital ET mode.

According to an exemplary aspect, the power supply circuit 1 includes a pre-regulator circuit 10, a switched-capacitor circuit 20, a supply modulator 30, and a filter circuit 40.

The pre-regulator circuit 10 is, for example, a direct current (DC)/DC converter that converts a DC voltage (e.g., first voltage) supplied from the DC power source 70 provided in the communication device 7 into a second voltage. The pre-regulator circuit 10 is configured to perform a step-up operation of making the voltage value of the second voltage larger than the voltage value of the first voltage and a step-down operation of making the voltage value of the second voltage smaller than the voltage value of the first voltage. That is, the pre-regulator circuit 10 is a buck-boost DC-DC converter.

The switched-capacitor circuit 20 is configured to generate a plurality of discrete voltages (e.g., a plurality of third voltages) by using the second voltage from the pre-regulator circuit 10 as an input voltage. The plurality of discrete voltages has voltage levels different from each other. The switched-capacitor circuit 20 may be referred to as a switched-capacitor voltage balancer.

The supply modulator 30 is configured to selectively output, to the filter circuit 40, at least one of the plurality of discrete voltages (e.g., the plurality of third voltages) generated by the switched-capacitor circuit 20 based on a digital control signal corresponding to the envelope signal. The supply modulator 30 outputs at least one discrete voltage selected from the plurality of discrete voltages. In the power supply circuit 1, the voltage level of an output voltage (e.g., a power supply voltage Vcc) of the supply modulator 30 can be changed with time by repeating the selection of the discrete voltage in the supply modulator 30 with time. Thus, the power supply circuit 1 can change the voltage level of the power supply voltage Vcc supplied to the power amplifier 2 with time.

The filter circuit 40 is configured to filter the output voltage of the supply modulator 30. The filter circuit 40 includes, for example, a low pass filter.

Moreover, the filter circuit 40 reduces the amplitude of a spike-shaped voltage of the output voltage output from the supply modulator 30. That is, the power supply circuit 1 includes the filter circuit 40, and thus can reduce the waveform distortion of the output voltage output from the supply modulator 30. Thus, it is possible to reduce a radio frequency component of the output voltage. As a result, in the power supply circuit 1, it is possible to reduce noise included in the power supply voltage Vcc, and thus it is possible to also reduce noise that enters the power amplifier 2 from the power supply circuit 1.

The power amplifier 2 has an input terminal, an output terminal, a power supply terminal, and a control terminal. The input terminal of the power amplifier 2 is connected to the signal processing circuit 5 of the communication device 7 through the signal input terminal T2. The output terminal of the power amplifier 2 is connected to an antenna 6 of the communication device 7 through the filter 3 and the antenna terminal T1. The power amplifier 2 amplifies a radio frequency transmission signal (referred to as a transmission signal below) in a predetermined band, which is outputted from the signal processing circuit 5 and outputs the amplified signal.

The filter 3 is connected between the output terminal of the power amplifier 2 and the antenna terminal T1. The filter 3 has a passband that includes a frequency band of a predetermined band. Thus, the filter 3 can cause the transmission signal in the predetermined band amplified by the power amplifier 2 to pass through the filter 3. In the radio frequency system 200, the transmission signal output from the power amplifier 2 is output to the antenna 6 through the filter 3 and the antenna terminal T1.

The control circuit 4 is connected to an RF signal processing circuit 51 of the signal processing circuit 5 through the first control terminal T3. The control circuit 4 is connected to the control terminal of the power amplifier 2. The control circuit 4 controls the magnitude and a supply timing of a bias current (or bias voltage) to be supplied to the control terminal of the power amplifier 2 by receiving a control signal from the RF signal processing circuit 51 of the signal processing circuit 5.

### (2.2) Communication Device

As illustrated in FIG. 5, the communication device 7 includes the radio frequency system 200, the signal processing circuit 5, the antenna 6, and the DC power source 70.

The DC power source 70 is, for example, a rechargeable battery. However, it is noted that the DC power source 70 is not limited to the rechargeable battery, and may be another battery as would be appreciated to one skilled in the art.

The antenna 6 is configured to transmit a transmission signal in a predetermined band output from the antenna terminal T1.

The signal processing circuit 5 includes the RF signal processing circuit 51 and a baseband signal processing circuit 52. The RF signal processing circuit 51 is, for example, a radio frequency integrated circuit (RF IC) and performs signal processing on a radio frequency signal. For example, the RF signal processing circuit 51 performs signal processing, such as upconverting, on a radio frequency signal (e.g., a transmission signal) outputted from the baseband signal processing circuit 52, and outputs the radio frequency signal subjected to the signal processing. The baseband signal processing circuit 52 is, for example, a baseband integrated circuit (BB IC). The baseband signal processing circuit 52 generates an I phase signal and a Q phase signal from a baseband signal. The baseband signal is, for example, an audio signal or an image signal inputted from the outside. The baseband signal processing circuit 52 performs IQ modulation processing by combining the I phase signal and the Q phase signal, and outputs the transmission signal. At this time, the transmission signal is generated as a modulation signal (e.g., an IQ signal) in which a carrier wave signal of a predetermined frequency is amplitude-modulated in a period longer than a period of the carrier wave signal.

The RF signal processing circuit 51 includes a control unit 511 that is configured to control the power supply circuit 1 and the power amplifier 2. The control unit 511 of the RF signal processing circuit 51 causes the supply modulator 30 to select the voltage level of the power supply voltage Vcc used in the power amplifier 2 from the voltage levels of the plurality of discrete voltages generated by the switched-capacitor circuit 20, based on the envelope signal of the radio frequency input signal input from the baseband signal processing circuit 52. Thus, the power supply circuit 1 outputs the power supply voltage Vcc based on the digital envelope tracking. The envelope signal is a signal indicating an envelope of a radio frequency signal (e.g., a modulated signal). The envelope value is, for example, (I²+Q²)^{1/2}. Here, (I, Q) represents a constellation point. The constellation point is a point representing a signal modulated by digital modulation on a constellation diagram. (I, Q) is determined by the baseband signal processing circuit 52, for example, based on transmission information. Some or all of the functions of the RF signal processing circuit 51 as the control unit 511 may be outside the RF signal processing circuit 51. For example, the baseband signal processing circuit 52 or the power supply circuit 1 may include some or all of the functions of the RF signal processing circuit 51 as the control unit 511. For example, the control function that causes the supply modulator 30 to select the voltage level of the power supply voltage Vcc does not need to be provided in the RF signal processing circuit 51, but may be provided in the power supply circuit 1.

### (2.3) Power Supply Circuit

As illustrated in FIG. 7, the power supply circuit 1 includes a pre-regulator circuit 10, a switched-capacitor circuit 20, a supply modulator 30, a filter circuit 40, a band select switch circuit 50, and a digital control circuit 60.

### (2.4) Pre-Regulator Circuit

As illustrated in FIG. 7, the pre-regulator circuit 10 includes an input terminal 110, a plurality (four in the example of FIG. 7) of output terminals 111 to 114, a plurality of inductor connection terminals 115 and 116, a control terminal 117, and a plurality (five in the example of FIG. 7) of switches S61, S62, S63, S71, and S72, a power inductor L71, and a plurality (four in the example of FIG. 7) of capacitors C61, C62, C63, and C64. The power inductor L71 is an inductor used to step up and/or step down a DC voltage (step-up, step-down, or step-up/down).

The input terminal 110 is an input terminal of a DC voltage. That is, the input terminal 110 is a terminal for receiving an input voltage from the DC power source 70 (see FIG. 7).

The output terminal 111 is an output terminal of a voltage V4. That is, the output terminal 111 is a terminal for supplying the voltage V4 to the switched-capacitor circuit 20. The output terminal 111 is connected to a node N4 of the switched-capacitor circuit 20.

The output terminal 112 is an output terminal of a voltage V3. That is, the output terminal 112 is a terminal for supplying the voltage V3 to the switched-capacitor circuit 20. The output terminal 112 is connected to a node N3 of the switched-capacitor circuit 20.

The output terminal 113 is an output terminal of a voltage V2. That is, the output terminal 113 is a terminal for supplying the voltage V2 to the switched-capacitor circuit 20. The output terminal 113 is connected to a node N2 of the switched-capacitor circuit 20.

The output terminal 114 is an output terminal of a voltage V1. That is, the output terminal 114 is a terminal for supplying the voltage V1 to the switched-capacitor circuit 20. The output terminal 114 is connected to a node N1 of the switched-capacitor circuit 20.

The inductor connection terminal 115 is connected to one end (e.g., the first end) of the power inductor L71. The inductor connection terminal 116 is connected to the other end (e.g., the second end) of the power inductor L71.

The control terminal 117 is an input terminal of a control signal Sg1. That is, the control terminal 117 is a terminal for receiving the control signal Sg1 for controlling the pre-regulator circuit 10. The control signal Sg1 is a signal for controlling on/off of the plurality of switches S61 to S63, S71, and S72 included in the pre-regulator circuit 10.

The switch S71 is connected between the input terminal 110 and one end (e.g., a first end) of the power inductor L71. Specifically, the switch S71 has a first terminal that is connected to the input terminal 110 and a second terminal that is connected to one end (e.g., the first end) of the power inductor L71 through the inductor connection terminal 115. In the above connection configuration, the switch S71 performs switching between connection and disconnection between the input terminal 110 and one end of the power inductor L71 by performing switching between on and off.

The switch S72 is connected between the one end (e.g., the first end) of the power inductor L71 and the ground. Specifically, the switch S72 has a first terminal that is connected to the one end (e.g., the first end) of the power inductor L71 via the inductor connection terminal 115 and a second terminal that is connected to the ground. In the above connection configuration, the switch S72 performs switching between connection and disconnection between the one end of the power inductor L71 and the ground by performing switching between on and off.

The switch S61 is connected between the other end (e.g., a second end) of the power inductor L71 and the output terminal 111. Specifically, the switch S61 has a first terminal that is connected to the other end (e.g., the second end) of the power inductor L71 and a second terminal that is connected to the output terminal 111. In the above connection configuration, the switch S61 performs switching between connection and disconnection between the other end of the power inductor L71 and the output terminal 111 by performing switching between on and off.

The switch S62 is connected between the other end (e.g., the second end) of the power inductor L71 and the output terminal 112. Specifically, the switch S62 has a first terminal that is connected to the other end (e.g., the second end) of the power inductor L71 and a second terminal that is connected to the output terminal 112. In the above connection configuration, the switch S62 performs switching between connection and disconnection between the other end of the power inductor L71 and the output terminal 112 by performing switching between on and off.

The switch S63 is connected between the other end (e.g., the second end) of the power inductor L71 and the output terminal 113. Specifically, the switch S63 has a first terminal that is connected to the other end (e.g., the second end) of the power inductor L71 and a second terminal that is connected to the output terminal 113. In the above connection configuration, the switch S63 performs switching between connection and disconnection between the other end of the power inductor L71 and the output terminal 113 by performing switching between on and off.

The capacitor C61 is connected between the output terminal 111 and the output terminal 112. One of two electrodes of the capacitor C61 is connected to the switch S61 and the output terminal 111, and the other of the two electrodes of the capacitor C61 is connected to the switch S62 and the output terminal 112, and one of two electrodes of the capacitor C62.

The capacitor C62 is connected between the output terminal 112 and the output terminal 113. One of the two electrodes of the capacitor C62 is connected to the switch S62 and the output terminal 112, and the other of the two electrodes of the capacitor C61. The other of the two electrodes of the capacitor C62 is connected to the switch S63 and the output terminal 113, and one of two electrodes of the capacitor C63.

The capacitor C63 is connected between the output terminal 113 and the output terminal 114. One of the two electrodes of the capacitor C63 is connected to the switch S63 and the output terminal 113, and the other of the two electrodes of the capacitor C62. The other of the two electrodes of the capacitor C63 is connected to the output terminal 114 and one of two electrodes of the capacitor C64.

The capacitor C64 is connected between the output terminal 114 and the ground. One of the two electrodes of the capacitor C64 is connected to the output terminal 114 and the other of the two electrodes of the capacitor C63. The other of the two electrodes of the capacitor C64 is connected to the ground.

According to an exemplary aspect, the plurality of switches S61 to S63 are controlled to be exclusively turned on. That is, only one of the switches S61 to S63 is turned on, and the rest of the switches S61 to S63 are turned off. The voltage levels of the voltages V1 to V4 can be changed depending on which of the switches S61 to S63 are turned on.

The pre-regulator circuit 10 configured as described above supplies charges to the switched-capacitor circuit 20 through at least one of the plurality of output terminals 111 to 113.

### (2.5) Switched-Capacitor Circuit

As illustrated in FIG. 7, the switched-capacitor circuit 20 includes a plurality (six in the example of FIG. 7) of capacitors C11 to C16, a plurality (four in the example of FIG. 7) of capacitors C21 to C24, and a plurality (sixteen in the example of FIG. 7), of switches S11 to S14, S21 to S24, S31 to S34, and S41 to S44, and a control terminal 120.

The control terminal 120 is an input terminal of a control signal Sg2 from the digital control circuit 60. The control signal Sg2 is a signal for controlling on/off of the plurality of switches S11 to S14, S21 to S24, S31 to S34, and S41 to S44 included in the switched-capacitor circuit 20.

Each of the plurality of capacitors C11 to C16 functions as a flying capacitor (e.g., a transfer capacitor). That is, each of the plurality of capacitors C11 to C16 is used to step up or step down the voltage (e.g., an input voltage) supplied from the pre-regulator circuit 10. More specifically, the plurality of capacitors C11 to C16 move charges between the capacitors C11 to C16 and the nodes N1 to N4 so that the voltages V1 to V4 (voltage with respect to the ground potential) that satisfy V1:V2:V3:V4=1:2:3:4 at the four nodes N1 to N4. The plurality of voltages V1 to V4 correspond to a plurality of discrete voltages having a plurality of discrete voltage levels, respectively. The voltage V1 is a voltage at the node N1, the voltage V2 is a voltage at the node N2, the voltage V3 is a voltage at the node N3, and the voltage V4 is a voltage at the node N4.

The capacitor C11 has two electrodes. One of the two electrodes of the capacitor C11 is connected to one end (e.g., the first end) of the switch S11 and one end (e.g., the first end) of the switch S12. The other of the two electrodes of the capacitor C11 is connected to one end (e.g., the first end) of the switch S21 and one end (e.g., the first end) of the switch S22.

The capacitor C12 has two electrodes. One of the two electrodes of the capacitor C12 is connected to the one end (e.g., the first end) of the switch S21 and the one end (e.g., the first end) of the switch S22. The other of the two electrodes of the capacitor C12 is connected to one end (e.g., the first end) of the switch S31 and one end (e.g., the first end) of the switch S32.

In the switched-capacitor circuit 20, the capacitor C12 is an example of a first capacitor, one of the two electrodes of the capacitor C12 configures a first electrode of the first capacitor, and the other of the two electrodes of the capacitor C12 configures a second electrode of the first capacitor.

The capacitor C13 has two electrodes. One of the two electrodes of the capacitor C13 is connected to one end (e.g., the first end) of the switch S31 and one end (e.g., the first end) of the switch S32. The other of the two electrodes of the capacitor C13 is connected to one end (e.g., the first end) of the switch S41 and one end (e.g., the first end) of the switch S42.

The capacitor C14 has two electrodes. One of the two electrodes of the capacitor C14 is connected to one end (e.g., the first end) of the switch S13 and one end (e.g., the first end) of the switch S14. The other of the two electrodes of the capacitor C14 is connected to one end (e.g., the first end) of the switch S23 and one end (e.g., the first end) of the switch S24.

The capacitor C15 has two electrodes. One of the two electrodes of the capacitor C15 is connected to the one end (e.g., the first end) of the switch S23 and the one end (e.g., the first end) of the switch S24. The other of the two electrodes of the capacitor C15 is connected to one end (e.g., the first end) of the switch S33 and one end (e.g., the first end) of the switch S34.

In the switched-capacitor circuit 20, the capacitor C15 is an example of a

second capacitor, one of the two electrodes of the capacitor C15 configures a third electrode of the second capacitor, and the other of the two electrodes of the capacitor C15 configures a fourth electrode of the second capacitor.

The capacitor C16 has two electrodes. One of the two electrodes of the capacitor C16 is connected to the one end (e.g., the first end) of the switch S33 and the one end (e.g., the first end) of the switch S34. The other of the two electrodes of the capacitor C16 is connected to one end (e.g., the first end) of the switch S43 and one end (e.g., the first end) of the switch S44.

Each of a set of the capacitors C11 and C14, a set of the capacitors C12 and C15, and a set of the capacitors C13 and C16 can be complementarily charged and discharged by repeating a first phase and a second phase.

In the first phase, the switches S12, S13, S22, S23, S32, S33, S42, and S43 are turned on. As a result, for example, one (first electrode) of the two electrodes of the capacitor C12 (first capacitor) is connected to the node N3. The other (second electrode) of the two electrodes of the capacitor C12 and one (third electrode) of the two electrodes of the capacitor C15 (second capacitor) is connected to the node N2. The other (fourth electrode) of the two electrodes of the capacitor C15 is connected to the node N1.

In the second phase, the switches S11, S14, S21, S24, S31, S34, S41, and S44 are turned on. As a result, for example, one (third electrode) of the two electrodes of the capacitor C15 (second capacitor) is connected to the node N3. The other (fourth electrode) of the two electrodes of the capacitor C15 (second capacitor) and one (first electrode) of the two electrodes of the capacitor C12 (first capacitor) are connected to the node N2. The other (second electrode) of the two electrodes of the capacitor C12 (first capacitor) is connected to the node N1.

By repeating the first phase and the second phase, for example, when one of the capacitors C12 and C15 is charged from the node N2, the other of the capacitors C12 and C15 can be discharged to the capacitor C23. That is, the capacitors C12 and C15 can be complementarily charged and discharged. The capacitors C12 and C15 are a pair of flying capacitors that are complementarily charged and discharged.

Similarly to the set of the capacitors C12 and C15, the set of the capacitors C11 and C14 are a pair of flying capacitors that are complementarily charged from the node and discharged to a smoothing capacitor, by appropriately switching the switch. Similarly to the set of the capacitors C12 and C15, the set of the capacitors C13 and C16 are a pair of flying capacitors that are complementarily charged from the node and discharged to a smoothing capacitor, by appropriately switching the switch.

Each of the plurality of capacitors C21 to C24 functions as a smoothing capacitor. That is, the capacitors C21 to C24 are configured to hold and smooth the voltages V1 to V4 at the nodes N1 to N4, respectively.

The capacitor C21 is connected between the node N1 and the ground. Specifically, one of the two electrodes of the capacitor C21 is connected to the node N1. On the other hand, the other (sixth electrode) of the two electrodes of the capacitor C21 is connected to the ground.

The capacitor C22 is connected between the node N2 and the node N1. Specifically, one of the two electrodes of the capacitor C22 is connected to the node N2. On the other hand, the other of the two electrodes of the capacitor C22 is connected to the node N1.

The capacitor C23 is connected between the node N3 and the node N2. Specifically, one of the two electrodes of the capacitor C23 is connected to the node N3. On the other hand, the other of the two electrodes of the capacitor C23 is connected to the node N2.

The capacitor C24 is connected between the node N4 and the node N3. Specifically, one of the two electrodes of the capacitor C24 is connected to the node N4. On the other hand, the other of the two electrodes of the capacitor C24 is connected to the node N3.

The switch S11 is connected between one of the two electrodes of the capacitor C11 and the node N3. Specifically, the one end (e.g., the first end) of the switch S11 is connected to one of the two electrodes of the capacitor C11. On the other hand, the other end (e.g., the second end) of the switch S11 is connected to the node N3.

The switch S12 is connected between one of the two electrodes of the capacitor C11 and the node N4. Specifically, the one end (e.g., the first end) of the switch S12 is connected to one of the two electrodes of the capacitor C11. On the other hand, the other end (e.g., the second end) of the switch S12 is connected to the node N4.

The switch S21 is connected between one (first electrode) of the two electrodes of the capacitor C12 (first capacitor) and the node N2. Specifically, the one end (e.g., the first end) of the switch S21 is connected to the one (first electrode) of the two electrodes of the capacitor C12 (first capacitor) and the other of the two electrodes of the capacitor C11. On the other hand, the other end (e.g., the second end) of the switch S21 is connected to the node N2. In the switched-capacitor circuit 20, the switch S21 is an example of a first switch.

The switch S22 is connected between one (first electrode) of the two electrodes of the capacitor C12 and the node N3. Specifically, the one end (e.g., the first end) of the switch S22 is connected to one (first electrode) of the two electrodes of the capacitor C12 and the other of the two electrodes of the capacitor C11. On the other hand, the other end (e.g., the second end) of the switch S22 is connected to the node N3. In the switched-capacitor circuit 20, the switch S22 is an example of a third switch.

The switch S31 is connected between the other (second electrode) of the two electrodes of the capacitor C12 (first capacitor) and the node N1. Specifically, the one end (e.g., the first end) of the switch S31 is connected to the other (second electrode) of the two electrodes of the capacitor C12 (first capacitor) and one of the two electrodes of the capacitor C13. On the other hand, the other end (e.g., the second end) of the switch S31 is connected to the node N1. In the switched-capacitor circuit 20, the switch S31 is an example of a fourth switch.

The switch S32 is connected between the other (second electrode) of the two electrodes of the capacitor C12 (first capacitor) and the node N2. Specifically, one end (e.g., the first end) of the switch S32 is connected to the other (second electrode) of the two electrodes of the capacitor C12 and one of the two electrodes of the capacitor C13. On the other hand, the other end (e.g., the second end) of the switch S32 is connected to the node N2. That is, the other end (e.g., the second end) of the switch S32 is connected to the other end (e.g., the second end) of the switch S21. In the switched-capacitor circuit 20, the switch S32 is an example of a second switch.

The switch S41 is connected between the other of the two electrodes of the capacitor C13 and the ground. Specifically, the one end (e.g., the first end) of the switch S41 is connected to the other of the two electrodes of the capacitor C13. On the other hand, the other end (e.g., the second end) of the switch S41 is connected to the ground.

The switch S42 is connected between the other of the two electrodes of the capacitor C13 and the node N1. Specifically, the one end (e.g., the first end) of the switch S42 is connected to the other of the two electrodes of the capacitor C13. On the other hand, the other end (e.g., the second end) of the switch S42 is connected to the node N1. That is, the other end (e.g., the second end) of the switch S42 is connected to the other end (e.g., the second end) of the switch S31.

The switch S13 is connected between one of the two electrodes of the capacitor C14 and the node N3. Specifically, one end (e.g., the first end) of the switch S13 is connected to one of the two electrodes of the capacitor C14. On the other hand, the other end (e.g., the second end) of the switch S13 is connected to the node N3. That is, the other end (e.g., the second end) of the switch S13 is connected to the other end (e.g., the second end) of the switch S11 and the other end (e.g., the second end) of the switch S22.

The switch S14 is connected between one of the two electrodes of the capacitor C14 and the node N4. Specifically, the one end (e.g., the first end) of the switch S14 is connected to one of the two electrodes of the capacitor C14. On the other hand, the other end (e.g., the second end) of the switch S14 is connected to the node N4. That is, the other end (e.g., the second end) of the switch S14 is connected to the other end (e.g., the second end) of the switch S12.

The switch S23 is connected between one (third electrode) of the two electrodes of the capacitor C15 (second capacitor) and the node N2. Specifically, the one end (e.g., the first end) of the switch S23 is connected to one (third electrode) of the two electrodes of the capacitor C15 and the other of the two electrodes of the capacitor C14. On the other hand, the other end (e.g., the second end) of the switch S23 is connected to the node N2. That is, the other end (e.g., the second end) of the switch S23 is connected to the other end (e.g., the second end) of the switch S21 and the other end (e.g., the second end) of the switch S32. In the switched-capacitor circuit 20, the switch S23 is an example of a fifth switch.

The switch S24 is connected between one (third electrode) of the two electrodes of the capacitor C15 (second capacitor) and the node N3. Specifically, the one end (e.g., the first end) of the switch S24 is connected to one (third electrode) of the two electrodes of the capacitor C15 and the other of the two electrodes of the capacitor C14. On the other hand, the other end (e.g., the second end) of the switch S24 is connected to the node N3. That is, the other end (e.g., the second end) of the switch S24 is connected to the other end (e.g., the second end) of the switch S11, the other end (e.g., the second end) of the switch S22, and the other end (e.g., the second end) of the switch S13. In the switched-capacitor circuit 20, the switch S24 is an example of a seventh switch.

The switch S33 is connected between the other of the two electrodes of the capacitor C15 (second capacitor) and the node N1. Specifically, the one end (e.g., the first end) of the switch S33 is connected to the other (fourth electrode) of the two electrodes of the capacitor C15 and one of the two electrodes of the capacitor C16. On the other hand, the other end (e.g., the second end) of the switch S33 is connected to the node N1. That is, the other end (e.g., the second end) of the switch S33 is connected to the other end (e.g., the second end) of the switch S31 and the other end (e.g., the second end) of the switch S42. In the switched-capacitor circuit 20, the switch S33 is an example of an eighth switch.

The switch S34 is connected between the other (fourth electrode) of the two electrodes of the capacitor C15 (second capacitor) and the node N2. Specifically, the one end (e.g., the first end) of the switch S34 is connected to the other (fourth electrode) of the two electrodes of the capacitor C15 and one of the two electrodes of the capacitor C16. On the other hand, the other end (e.g., the second end) of the switch S34 is connected to the node N2. That is, the other end (e.g., the second end) of the switch S34 is connected to the other end (e.g., the second end) of the switch S21, the other end (e.g., the second end) of the switch S32, and the other end (e.g., the second end) of the switch S23. In the switched-capacitor circuit 20, the switch S34 is an example of a sixth switch.

The switch S43 is connected between the other of the two electrodes of the capacitor C16 and the ground. Specifically, the one end (e.g., the first end) of the switch S43 is connected to the other of the two electrodes of the capacitor C16. On the other hand, the other end (e.g., the second end) of the switch S43 is connected to the ground.

The switch S44 is connected between the other of the two electrodes of the capacitor C16 and the node N1. Specifically, the one end (e.g., the first end) of the switch S44 is connected to the other of the two electrodes of the capacitor C16. On the other hand, the other end (e.g., the second end) of the switch S44 is connected to the node N1. That is, the other end (e.g., the second end) of the switch S44 is connected to the other end (e.g., the second end) of the switch S31, the other end (e.g., the second end) of the switch S42, and the other end (e.g., the second end) of the switch S33.

On and off are complementarily switched between a first set of switches including the switches S12, S13, S22, S23, S32, S33, S42, and S43 and a second set of switches including the switches S11, S14, S21, S24, S31, S34, S41, and S44. Specifically, in the first phase, the first set of switches is turned on, and the second set of switches is turned off. Conversely, in the second phase, the first set of switches is turned off, and the second set of switches is turned on.

For example, charging from the capacitors C11 to C13 to the capacitors C21 to C24 is performed in one of the first phase and the second phase, and charging from the capacitors C14 to C16 to the capacitors C21 to C24 is performed in the other of the first phase and the second phase. That is, the capacitors C21 to C24 are normally charged from the capacitors C11 to C13 or the capacitors C14 to C16. Thus, even though a current flows from the nodes N1 to N4 to the supply modulator 30 at a high speed, it is possible to suppress the potential fluctuations of the nodes N1 to N4 because the charges are replenished at the nodes N1 to N4 at a high speed.

By operating as described above, the switched-capacitor circuit 20 can maintain substantially the same voltage at both ends of each of the capacitors C21 to C24. Specifically, the voltages V1 to V4 (voltage with respect to the ground potential) that satisfy V1:V2:V3:V4=1:2:3:4 are maintained at the four nodes N1 to N4. The voltage levels of the voltages V1 to V4 correspond to a plurality of discrete voltage levels supplied to the supply modulator 30 by the switched-capacitor circuit 20.

It is noted that the t voltage ratio V1:V2:V3:V4 is not limited to 1:2:3:4. For example, the voltage ratio V1:V2:V3:V4 may be 1:2:4:8 in another exemplary aspect.

### (2.6) Supply Modulator

As illustrated in FIG. 7, the supply modulator 30 includes a plurality (four in the example of FIG. 7) of input terminals 131 to 134, a plurality (four in the example of FIG. 7) of switches S51 to S54, an output terminal 130, and a control terminal 135.

The output terminal 130 is connected to the filter circuit 40. The output terminal 130 is a terminal for supplying a voltage selected from the voltages V1 to V4 to the power amplifier 2 through the filter circuit 40 as the power supply voltage Vcc.

The plurality of input terminals 131 to 134 are connected to the nodes N4 to N1 of the switched-capacitor circuit 20, respectively. The plurality of input terminals 131 to 134 are terminals for receiving the voltages V4 to V1 from the switched-capacitor circuit 20.

The control terminal 135 is an input terminal of a control signal Sg3 from the digital control circuit 60. The control signal Sg3 is a signal for controlling on/off of the plurality of switches S51 to S54 included in the supply modulator 30. The supply modulator 30 controls on/off of the plurality of switches S51 to S54 based on the control signal Sg3.

The switch S51 is connected between the input terminal 131 and the output terminal 130. Specifically, the switch S51 has a first terminal that is connected to the input terminal 131 and a second terminal that is connected to the output terminal 130. In the above connection configuration, the switch S51 performs switching between the connection and the disconnection between the input terminal 131 and the output terminal 130 by performing switching between on and off.

The switch S52 is connected between the input terminal 132 and the output terminal 130. Specifically, the switch S52 has a first terminal that is connected to the input terminal 132 and a second terminal that is connected to the output terminal 130. In the above connection configuration, the switch S52 performs switching between the connection and the disconnection between the input terminal 132 and the output terminal 130 by performing switching between on and off. In the supply modulator 30, the switch S52 is an example of a tenth switch.

The switch S53 is connected between the input terminal 133 and the output terminal 130. Specifically, the switch S53 has a first terminal that is connected to the input terminal 133 and a second terminal that is connected to the output terminal 130. In the above connection configuration, the switch S53 performs switching between the connection and the disconnection between the input terminal 133 and the output terminal 130 by performing switching between on and off. In the supply modulator 30, the switch S53 is an example of a ninth switch.

The switch S54 is connected between the input terminal 134 and the output terminal 130. Specifically, the switch S54 has a first terminal that is connected to the input terminal 134 and a second terminal that is connected to the output terminal 130. In the above connection configuration, the switch S54 performs switching between the connection and the disconnection between the input terminal 134 and the output terminal 130 by performing switching between on and off.

The plurality of switches S51 to S54 are controlled to be exclusively turned on. That is, only one of the switches S51 to S54 is turned on, and the rest of the switches S51 to S54 are turned off. As a result, the supply modulator 30 can output one voltage selected from the voltages V1 to V4.

The supply modulator 30 has the above configuration, so that the digital control signal corresponding to the envelope signal is input from the control terminal 135, and controls on/off of the plurality of switches S51 to S54 based on the digital control signal input from the control terminal 135 to select at least one of the plurality of voltages V1 to V4 generated by the switched-capacitor circuit 20. The supply modulator 30 outputs the selected voltage.

It should be appreciated that the waveform of the output voltage of the supply modulator 30 does not need to be a rectangular wave including only a plurality of discrete voltages. Specifically, the waveform of the output voltage of the supply modulator 30 becomes a waveform distorted from the rectangular wave by an overshoot voltage (e.g., a spike-shaped voltage) being generated when the voltage transitions from a discrete voltage having a relatively low voltage level to a discrete voltage having a relatively high voltage level. In addition, the waveform of the output voltage of the supply modulator 30 becomes a waveform distorted from the rectangular wave by an undershoot voltage (e.g., a spike-shaped voltage) being generated when the voltage transitions from the discrete voltage having a relatively high voltage level to the discrete voltage having a relatively low voltage level. The distortion of the waveform of the output voltage of the supply modulator 30 as described above causes noise. The amplitude of the spike-shaped voltage increases as the absolute value of a voltage change rate (dV/dt) increases.

### (2.7) Band Select Switch Circuit

As illustrated in FIG. 7, the band select switch circuit 50 includes a common terminal 150, a plurality (four in the example of FIG. 7) of switches S81 to S84, and a plurality (four in the example of FIG. 7) of selection terminals 151 to 154, and a control terminal 155.

The common terminal 150 of the band select switch circuit 50 is connected to the output terminal 130 of the supply modulator 30. For example, a plurality of power amplifiers corresponding to communication bands that are different from each other are connected to the plurality of selection terminals 151 to 154, respectively. In the example illustrated in FIG. 7, the power amplifier 2 is connected to one selection terminal 151 among the plurality of selection terminals 151 to 154 through the filter circuit 40.

The control terminal 155 is an input terminal of a control signal Sg4. That is, the control terminal 155 is a terminal for receiving the control signal Sg4 indicating one of a plurality of communication bands. The band select switch circuit 50 controls on/off of the plurality of switches S81 to S84 such that the power amplifier corresponding to the communication band indicated by the control signal Sg4 is connected to the supply modulator 30.

The switch S81 is connected between the common terminal 150 and the selection terminal 151. Specifically, the switch S81 has a first terminal that is connected to the common terminal 150 and a second terminal that is connected to the selection terminal 151. In the above connection configuration, the switch S81 performs switching between the connection and the disconnection between the common terminal 150 and the selection terminal 151 by performing switching between on and off.

The switch S82 is connected between the common terminal 150 and the selection terminal 152. Specifically, the switch S82 has a first terminal that is connected to the common terminal 150 and a second terminal that is connected to the selection terminal 152. In the above connection configuration, the switch S82 performs switching between the connection and the disconnection between the common terminal 150 and the selection terminal 152 by performing switching between on and off.

The switch S83 is connected between the common terminal 150 and the selection terminal 153. Specifically, the switch S83 has a first terminal that is connected to the common terminal 150 and a second terminal that is connected to the selection terminal 153. In the above connection configuration, the switch S83 performs switching between the connection and the disconnection between the common terminal 150 and the selection terminal 153 by performing switching between on and off.

The switch S84 is connected between the common terminal 150 and the selection terminal 154. Specifically, the switch S84 has a first terminal that is connected to the common terminal 150 and a second terminal that is connected to the selection terminal 154. In the above connection configuration, the switch S84 performs switching between the connection and the disconnection between the common terminal 150 and the selection terminal 154 by performing switching between on and off.

In the example in FIG. 7, the plurality of switches S81 to S84 are controlled to be exclusively turned on. That is, only any one of the switches S81 to S84 is turned on, and the rest of the switches S81 to S84 are turned off.

### (2.8) Filter Circuit

As illustrated in FIG. 7, the filter circuit 40 includes an input terminal 141, an output terminal 142, and a plurality of functional elements. The plurality of functional elements includes a plurality (three in the example of FIG. 7) of inductors L0, L1, and L2 and a plurality (two in the example of FIG. 7) of capacitors C1 and C2.

The input terminal 141 is configured as an input terminal of a voltage selected by the supply modulator 30. That is, the input terminal 141 is a terminal for receiving the voltage selected from the plurality of voltages V1 to V4 according to the exemplary aspect. In the example of FIG. 7, the input terminal 141 is connected to the output terminal 130 of the supply modulator 30 through the band select switch circuit 50.

The output terminal 142 is a terminal from which the voltage filtered by the filter circuit 40 is output. The voltage output from the output terminal 142 of the filter circuit 40 is the power supply voltage Vcc supplied to the power amplifier 2.

The inductor L0 is connected between the input terminal 141 and the output terminal 142. More specifically, one end (e.g., the first end) of the inductor L0 is connected to the input terminal 141, and the other end (e.g., the second end) of the inductor L0 is connected to the output terminal 142.

The inductor L1 and the capacitor C1 are connected in series between the one end of the inductor L0 and the ground. More specifically, one end (e.g., the first end) of the inductor L1 is connected to the one end (e.g., the first end) of the inductor L0, the other end (e.g., the second end) of the inductor L1 is connected to one of two electrodes of the capacitor C1, and the other of the two electrodes of the capacitor C1 is connected to the ground. That is, the filter circuit 40 includes a first LC series circuit 41 (see FIG. 3) including the inductor L1 (also referred to as a first inductor L1 below) and the capacitor C1 (also referred to as a first capacitor C1 below).

The inductor L2 and the capacitor C2 are connected in series between the other end of the inductor L0 and the ground. More specifically, one end (e.g., the first end) of the inductor L2 is connected to the other end (e.g., the second end) of the inductor L0, the other end (e.g., the second end) of the inductor L2 is connected to one of two electrodes of the capacitor C2, and the other of the two electrodes of the capacitor C2 is connected to the ground. That is, the filter circuit 40 includes a second LC series circuit 42 (see FIG. 3) including the inductor L2 (also referred to as a second inductor L2 below) and the capacitor C2 (also referred to as a second capacitor C2 below).

The filter circuit 40 configures a low pass filter. Thus, the filter circuit 40 can reduce a radio frequency component included in the power supply voltage Vcc. For example, when a predetermined band is a frequency band for Frequency Division Duplex (FDD), the filter circuit 40 is configured to reduce a component of a downlink operation band of the predetermined band.

The filter characteristic of the filter circuit 40 has two attenuation poles. The frequency of one of the two attenuation poles is determined by the circuit constant of each of the first inductor L1 and the first capacitor C1 in the first LC series circuit. The frequency of the other attenuation pole of the two attenuation poles is determined by the circuit constant of each of the second inductor L2 and the second capacitor C2 in the second LC series circuit.

The filter circuit 40 is configured to reduce the amplitude of a spike-shaped voltage of the output voltage output from the supply modulator 30. That is, the power supply circuit 1 includes the filter circuit 40, and thus reduces the waveform distortion of the output voltage output from the supply modulator 30. Thus, it is possible to reduce a radio frequency component of the output voltage. As a result, in the power supply circuit 1, it is possible to reduce noise included in the power supply voltage Vcc, and thus it is possible to reduce noise that enters the power amplifier 2 from the power supply circuit 1.

### (2.9) Digital Control Circuit

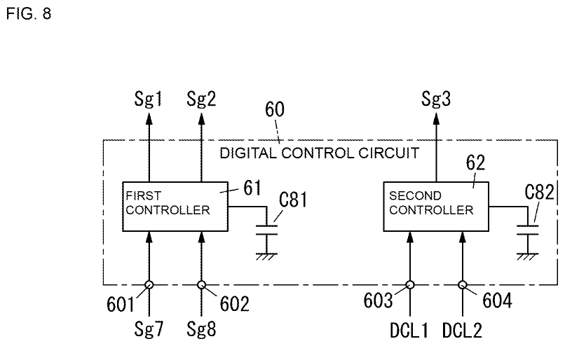

As illustrated in FIG. 8, the digital control circuit 60 includes a first controller 61, a second controller 62, two capacitors C81 and C82, and four control terminals 601 to 604. The four control terminals 601 to 604 of the digital control circuit 60 are connected to the four second control terminals T5 (see FIG. 5) provided in the radio frequency system 200 in a one-to-one manner. Therefore, the four control terminals 601 to 604 of the digital control circuit 60 are connected to the RF signal processing circuit 51 (see FIG. 5) of the communication device 7.

The first controller 61 receives a source-synchronous digital control signal from the RF signal processing circuit 51 through the control terminals 601 and 602, and processes the digital control signal and generates the control signal Sg1 and the control signal Sg2.

In the first controller 61, one set of a clock signal Sg7 and a data signal Sg8 is used as the digital control signals for the pre-regulator circuit 10 and the switched-capacitor circuit 20. The clock signal Sg7 is input to the first controller 61 through the control terminal 601. The data signal Sg8 is input to the first controller 61 through the control terminal 602.

The second controller 62 is configured to process digitally controlled level (DCL) signals DCL1 and DCL2, which are digital control signals received from the RF signal processing circuit 51 through the control terminals 603 and 604, and generates the control signal Sg3. The digitally controlled level signals DCL1 and DCL2 correspond to envelope signals.

Each of the digitally controlled level signals DCL1 and DCL2 is a 1-bit signal. Each of the voltages V1 to V4 is represented by a combination of two 1-bit signals. For example, V1, V2, V3, and V4 are represented by “00”, “01”, “10”, and “11”, respectively. A Gray code may be used to express the voltage level. In the above case, two digitally controlled level signals are configured to control the supply modulator 30, but the number of digitally controlled level signals is not limited to two. For example, any number of digitally controlled level signals, one or three or more, may be used in accordance with the number of voltage levels that can be selected by the supply modulator 30. The digital control signal used to control the supply modulator 30 is not limited to the digitally controlled level signal.

The capacitor C81 is connected between the first controller 61 and the ground. For example, the capacitor C81 is connected between a power line for supplying power to the first controller 61 and the ground, and functions as a bypass capacitor. The capacitor C82 is connected between the second controller 62 and the ground. For example, the capacitor C82 is connected between a power line for supplying power to the second controller 62 and the ground, and functions as a bypass capacitor.

### (3) Structure of Tracker Module

As illustrated in FIGS. 1 to 4, the tracker module 100 according to Embodiment 1 includes the module laminate 9, the IC chip 80, the plurality (ten in the example of FIG. 7) of capacitors C11 to C16 and C21 to C24 of the switched-capacitor circuit 20, the plurality (four in FIG. 7) of capacitors C61 to C64 of the pre-regulator circuit 10, the inductors L0 to L2 and the capacitors C1 and C2 of the filter circuit 40, and the plurality of external connection terminals 160. The tracker module 100 according to Embodiment 1 further includes a resin layer 94. The tracker module 100 according to Embodiment 1 has a circuit configuration in which the power inductor L71 is removed from the circuit configuration of the power supply circuit 1. That is, the tracker module 100 does not include the power inductor L71. In FIG. 1, the resin layer 94 is not illustrated.

### (3.1) Module Laminate

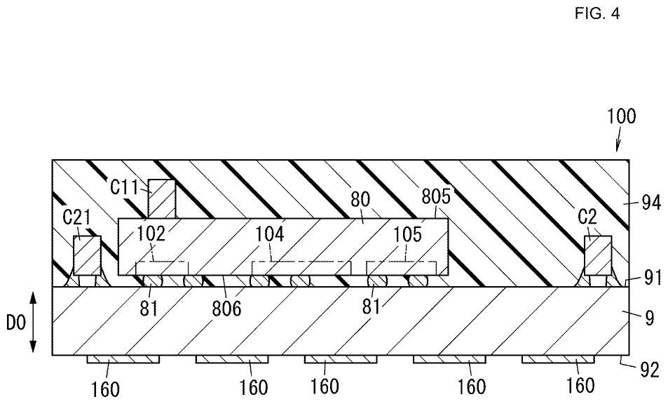

As illustrated in FIGS. 1 and 4, the module laminate 9 has a main surface 91 and a main surface 92 that face each other in a thickness direction D0 of the module laminate 9. For purposes of this disclosure, the term “facing” means facing geometrically rather than physically. In a plan view in the thickness direction D0 of the module laminate 9, an outer edge of the module laminate 9 has, for example, a rectangular shape, but may have a shape other than a rectangular shape. The module laminate 9 is, for example, a multilayer laminate in which a plurality of dielectric layers and a plurality of conductive layers (not illustrated) are laminated. A material of each conductive layer is, for example, copper. The plurality of conductive layers includes a ground layer. The ground layer of the module laminate 9 is electrically connected to at least one external ground terminal included in the plurality of external connection terminals 160 through a via conductor or the like of the module laminate 9.

The module laminate 9 is, for example, a low temperature co-fired ceramics (LTCC) board. The module laminate 9 is not limited to the LTCC board, and may be, for example, a printed wiring board, a high temperature co-fired ceramics (HTCC) board, a resin multilayer laminate, or a component-embedded board.

### (3.2) IC Chip

As illustrated in FIGS. 1 and 4, the IC chip 80 is disposed at the module laminate 9. For purposes of this disclosure, the phrase “the IC chip 80 is disposed at the module laminate 9” includes the meanings that the IC chip 80 is mechanically connected to the module laminate 9 and that the IC chip 80 is electrically connected to the module laminate 9. The IC chip 80 is disposed on the main surface 91 of the module laminate 9. The IC chip 80 is, for example, a Si-based IC chip including a silicon substrate. The Si-based IC chip may include a silicon-on-insulator (SOI) substrate instead of a silicon substrate. The IC chip 80 is not limited to a Si-based IC chip, and may be, for example, a GaAs-based IC chip, a SiGe-based IC chip, or a GaN-based IC chip.

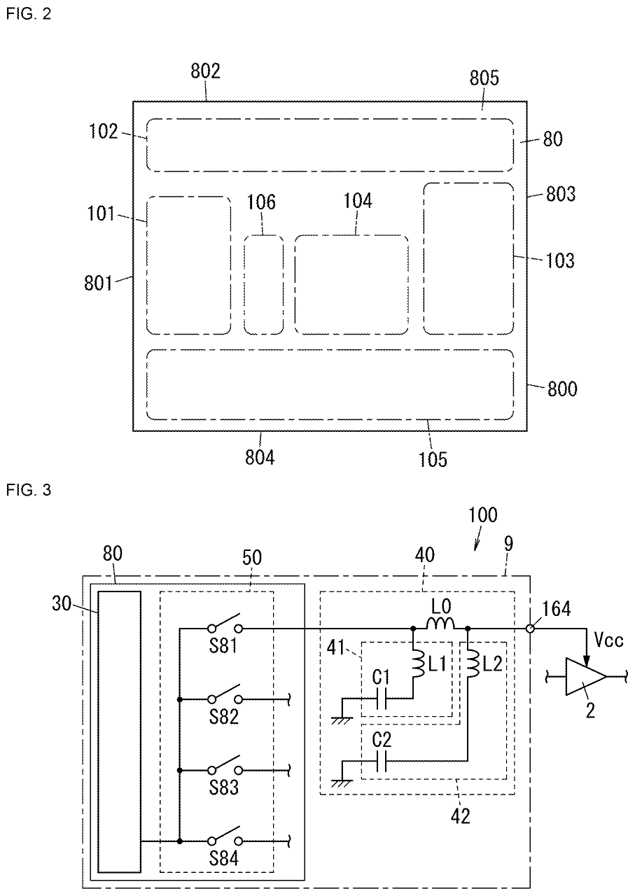

As illustrated in FIGS. 1 and 2, an outer edge 800 of the IC chip 80 has a rectangular shape in a plan view in the thickness direction D0 of the module laminate 9. The outer edge 800 of the IC chip 80 includes a first side 801, a second side 802, a third side 803, and a fourth side 804. The first side 801, the second side 802, the third side 803, and the fourth side 804 are arranged in the order of the first side 801, the second side 802, the third side 803, and the fourth side 804. At the outer edge 800, the first side 801 and the third side 803 are parallel to each other, and the second side 802 and the fourth side 804 are parallel to each other.

As illustrated in FIG. 2, the IC chip 80 includes a PR switch portion 101, an SC switch portion 102, an SC switch portion 103, an SM switch portion 104, a BS switch portion 105, a digital control unit 106, and a plurality of an input and output electrode 81. The SC switch portion 102 corresponds to a first switch portion. The SM switch portion 104 corresponds to a second switch portion.

The PR switch portion 101 includes a plurality of switches S61 to S63, S71, and S72 (see FIG. 7) of the pre-regulator circuit 10. In the IC chip 80, the PR switch portion 101 is disposed along the first side 801.

The SC switch portion 102 includes a plurality of switches S11, S12, S21, S22, S31, S32, S41, and S42 (see FIG. 7) of the switched-capacitor circuit 20. Specifically, the SC switch portion 102 includes a series circuit in which the plurality of switches S12, S11, S22, S21, S32, S31, S42, and S41 are connected in this order. In the IC chip 80, the SC switch portion 102 is disposed along the second side 802.

The SC switch portion 103 includes a plurality of switches S13, S14, S23, S24, S33, S34, S43, and S44 (see FIG. 7) of the switched-capacitor circuit 20. Specifically, the SC switch portion 103 includes a series circuit in which the plurality of switches S14, S13, S24, S23, S34, S33, S44, and S43 are connected in this order. In the IC chip 80, the SC switch portion 103 is disposed along the third side 803.

The SM switch portion 104 includes a plurality of switches S51 to S54 (see FIG. 7) of the supply modulator 30. In the IC chip 80, the SC switch portion 103 are disposed to be adjacent to the SM switch portion 104.

The BS switch portion 105 includes a plurality of switches S81 to S84 (see FIG. 7) included in the band select switch circuit 50. In the IC chip 80, the BS switch portion 105 is disposed to be adjacent to the SM switch portion 104. In the IC chip 80, the BS switch portion 105 is disposed along the fourth side 804.

The digital control unit 106 includes the first controller 61 and the second controller 62 (see FIG. 7) of the digital control circuit 60. The digital control unit 106 is disposed at the central portion of the IC chip 80 in a plan view in the thickness direction D0 of the module laminate 9, and is surrounded by the PR switch portion 101, the SM switch portion 104, and the BS switch portion 105.

In the IC chip 80, each of the plurality of switches S11 to S14, S21 to S24, S31 to S34, S41 to S44, S51 to S54, S61 to S63, S71, S72, and S81 to S84 is, for example, a metal oxide semiconductor field effect transistor (MOSFET).

### (3.3) Plurality of Capacitors of Switched-Capacitor Circuit

The capacitor C11 included in the switched-capacitor circuit 20 is stacked on the IC chip 80 as illustrated in FIG. 4. For purposes of this disclosure, the phrase that “the capacitor C11 is stacked on the IC chip 80” means that the capacitor C11 is mounted on the IC chip 80. The capacitor C11 is a flying capacitor in an exemplary aspect.

Specifically, the IC chip 80 has a main surface 805 and a main surface 806 that face each other in the thickness direction D0 of the module laminate 9. The main surface 806 of the IC chip 80 faces the main surface 91 of the module laminate 9. The capacitor C11 is mounted on the main surface 805 of the IC chip 80. In other words, the IC chip 80 is located between the at least one capacitor C11 and the main surface 91 of the module laminate 9.

In a plan view in the thickness direction D0 of the module laminate 9, the capacitor C11 stacked on the IC chip 80 overlaps the SC switch portion 102 of the IC chip 80 as illustrated in FIG. 4. In the plan view in the thickness direction D0 of the module laminate 9, the capacitor C11 stacked on the IC chip 80 does not overlap the SM switch portion 104 of the IC chip 80 as illustrated in FIG. 4.

Among the plurality of capacitors C11 to C16 and C21 to C24 of the switched-capacitor circuit 20, the capacitors C12 to C16 and C21 to C24 are disposed at the module laminate 9. For purposes of this disclosure, the phrase that “the capacitors C12 to C16 and C21 to C24 are disposed at the module laminate 9” includes a case where the capacitors C12 to C16 and C21 to C24 are mechanically connected to the module laminate 9 and a case where the capacitor C12 to C16 and C21 to C24 are electrically connected to the module laminate 9. More specifically, the capacitors C12 to C16 and C21 to C24 are mounted in an SC capacitance portion 902 on the main surface 91 of the module laminate 9.

Each of the plurality of capacitors C11 to C16 and C21 to C24 is a chip capacitor. That is, the plurality of capacitors C11 to C16 and C21 to C24 are surface-mounted capacitors.

### (3.4) Plurality of Capacitors of Pre-Regulator Circuit

The plurality (four in the example of FIG. 7) of capacitors C61 to C64 of the pre-regulator circuit 10 are disposed at the module laminate 9. More specifically, the plurality of capacitors C61 to C64 are mounted in a PR capacitance portion 901 (see FIG. 1) on the main surface 91 of the module laminate 9. Each of the plurality of capacitors C61 to C64 is a chip capacitor. That is, each of the plurality of capacitors C61 to C64 is a surface-mounted capacitor.

In the tracker module 100, the plurality of capacitors C61 to C64 are adjacent to the IC chip 80 in a plan view in the thickness direction D0 of the module laminate 9. The plurality of capacitors C61 to C64 of the pre-regulator circuit 10 are disposed along the first side 801 of the IC chip 80 in the plan view in the thickness direction D0 of the module laminate 9.

### (3.5) Inductor and Capacitor of Filter Circuit

The plurality (three in FIG. 7) of inductors L0 to L2 and one or more (two in FIG. 7) capacitors C1 and C2 included in the filter circuit 40 are disposed at the module laminate 9. More specifically, the plurality of inductors L0 to L2 and the capacitors C1 and C2 are mounted in a filter circuit portion 903 (see FIG. 1) on the main surface 91 of the module laminate 9. Each of the plurality of inductors L0 to L2 is a chip inductor. That is, each of the plurality of inductors L0 to L2 is a surface-mounted inductor. Each of the capacitors C1 and C2 is a chip capacitor. That is, each of the capacitors C1 and C2 is a surface-mounted capacitor.

### (3.6) Input and Output Electrode

As illustrated in FIG. 4, the plurality of input and output electrodes 81 are electrically connected to circuit components other than the IC chip 80, which are disposed on the main surface 91 of the module laminate 9, the plurality of external connection terminals 160 disposed on the main surface 92 of the module laminate 9, or the like through wiring portions, via conductor portions, or the like formed at the module laminate 9.

### (3.7) External Connection Terminal

The plurality of external connection terminals 160 illustrated in FIG. 4 include an input terminal 161 (see FIG. 5), a plurality (four) of input control terminals 165 (only one is illustrated in FIG. 5), an output terminal 164 (see FIG. 5), and a ground terminal (not illustrated). The input terminal 161 is connected to the input terminal 110 of the pre-regulator circuit 10. The input terminal 161 is a terminal connected to the DC power source 70 through the power source connection terminal T4 provided in the radio frequency system 200. That is, the input terminal 110 of the pre-regulator circuit 10 is connected to the DC power source 70 through the input terminal 161. The four input control terminals 165 are terminals connected to the four second control terminals T5. The four input control terminals 165 are connected to the control terminals 601 to 604 of the digital control circuit 60. The output terminal 164 is connected to the output terminal 142 of the filter circuit 40. The output terminal 164 is a terminal to which the power supply voltage Vcc is output, and is connected to the power supply terminal of the power amplifier 2. The plurality of ground terminals are terminals to which a ground potential is applied.

### (3.8) Resin Layer

The resin layer 94 is disposed on the main surface 91 of the module laminate 9, and covers a portion of each of the plurality of circuit components included in the tracker module 100 and the main surface 91 of the module laminate 9. The plurality of circuit components includes the IC chip 80, the plurality of capacitors C11 to C16, the plurality of capacitors C21 to C24, and the plurality of capacitors C61 to C64. The resin layer 94 contains resin (for example, epoxy resin). The resin layer 94 may contain a filler in addition to the resin. The resin layer 94 is electrically insulating.

### (3.9) Disposition of Tracker Module

The tracker module 100 is disposed, for example, at a motherboard provided in the radio frequency system 200. More specifically, the tracker module 100 is electrically and mechanically connected to the motherboard by the plurality of external connection terminals 160. Thus, in the radio frequency system 200, for example, the output terminal of the tracker module 100 (output terminal 142 of the filter circuit 40) is connected to the power supply terminal of the power amplifier 2 disposed at the motherboard.

### (4) Structure of Radio Frequency System

The radio frequency system 200 includes a motherboard (not illustrated) and a plurality of electronic components disposed on the motherboard. The motherboard is, for example, a printed wiring board. The plurality of electronic components includes the tracker module 100, the power inductor L71, the power amplifier 2, and the filter 3.

### (5) Configuration of Communication Device

The communication device 7 includes the radio frequency system 200, the signal processing circuit 5 disposed at the motherboard of the radio frequency system 200, and the antenna 6. The communication device 7 may include a second motherboard at which the radio frequency system 200 and the signal processing circuit 5 are disposed, separately from the first motherboard which is the motherboard of the radio frequency system 200.

### (6) Effects

The tracker module 100 according to Embodiment 1 includes the module laminate 9, the IC chip 80, and the capacitor C11. The IC chip 80 is disposed at the module laminate 9. The capacitor C11 is included in the switched-capacitor circuit 20. The switched-capacitor circuit 20 is configured to generate a plurality of discrete voltages based on the input voltage. The IC chip 80 includes the switches S11 to S44 included in the switched-capacitor circuit 20 and the switches S51 to S54 included in the supply modulator 30. The supply modulator 30 is configured to selectively output at least one of the plurality of discrete voltages to the power amplifier 2. The capacitor C11 is stacked on the IC chip.

As a result, in the switched-capacitor circuit 20, a wiring portion between the switches S11 to S44 and the capacitor C11 can be shortened. Thus, the resistance or parasitic capacitance in the wiring portion of the switched-capacitor circuit 20 can also be reduced and the deterioration in the output characteristics of the tracker module 100 can be reduced. Since the capacitor C11 included in the switched-capacitor circuit 20 is stacked on the IC chip 80, the area of the main surface 91 of the module laminate 9 can be reduced. Therefore, it is possible to decrease the projected area of the tracker module 100 in a plan view in the thickness direction D0 of the module laminate 9.

In the tracker module 100 according to Embodiment 1, the IC chip 80 is located between the capacitor C11 and the module laminate 9.

As a result, in the switched-capacitor circuit 20, the wiring portion between the switches S11 to S44 and the capacitor C11 can be shortened. Thus, the resistance or parasitic capacitance in the wiring portion of the switched-capacitor circuit 20 can be reduced and the deterioration in the output characteristics of the tracker module 100 can also be reduced. Since the capacitor C11 included in the switched-capacitor circuit 20 and the IC chip 80 overlap each other in a plan view in the thickness direction D0 of the module laminate 9, it is possible to decrease the area of the main surface 91 of the module laminate 9. Therefore, the projected area of the tracker module 100 can be decreased in a plan view in the thickness direction D0 of the module laminate 9.

In the tracker module 100 according to Embodiment 1, the IC chip 80 has the main surface 805 and the main surface 806 that face each other. The main surface 806 of the IC chip 80 faces the module laminate 9. The capacitor C11 is disposed on the main surface 805 of the IC chip 80.

As a result, in the switched-capacitor circuit 20, the wiring portion between the switches S11 to S44 and the capacitor C11 can be shortened. Thus, the resistance or parasitic capacitance in the wiring portion of the switched-capacitor circuit 20 can be reduced and the deterioration in the output characteristics of the tracker module 100 can also be reduced. Since the capacitor C11 is disposed on the main surface 805 of the IC chip 80, it is possible to decrease the area of the main surface 91 of the module laminate 9. Therefore, the projected area of the tracker module 100 can be decreased in a plan view in the thickness direction D0 of the module laminate 9.

In the tracker module 100 according to Embodiment 1, the IC chip 80 includes the SC switch portion 102 and the SM switch portion 104. The SC switch portion 102 includes the switches S11, S12, S21, S22, S31, S32, S41, and S42 included in the switched-capacitor circuit 20. The SM switch portion 104 includes the switches S51 to S54 included in the supply modulator 30. The capacitor C11 overlaps the SC switch portion 102 in a plan view in the thickness direction D0 of the module laminate 9. As a result, in the switched-capacitor circuit 20, it is possible to reduce a wiring portion between any of the switches S11, S12, S21, S22, S31, S32, S41, and S42 and the capacitor C11. Thus, it is possible to reduce the resistance or parasitic capacitance in the wiring portion of the switched-capacitor circuit 20 and to reduce the deterioration in the output characteristics of the tracker module 100.

In the tracker module 100 according to Embodiment 1, the capacitor C11 does not overlap the SM switch portion 104 in a plan view in the thickness direction D0 of the module laminate 9. As a result, since a distance between the capacitor C11 and the supply modulator 30 is not too close, it is possible to reduce the parasitic capacitance between the switched-capacitor circuit 20 and the supply modulator 30.

### Embodiment 2

### (1) Configuration

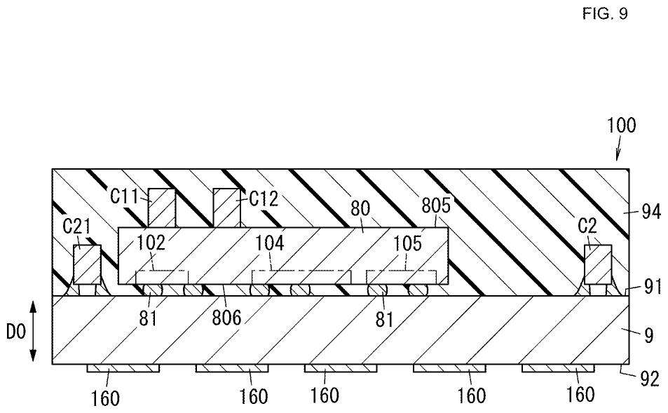

In a tracker module 100 according to Embodiment 2, as illustrated in FIG. 9, a plurality (two in FIG. 9) of capacitors are stacked on an IC chip 80. The plurality of capacitors stacked on the IC chip 80 are flying capacitors.

In the tracker module 100 according to Embodiment 2, capacitors C11 and C12, which are some of a plurality of capacitors C11 to C16 (e.g., flying capacitors) of a switched-capacitor circuit 20 (see FIG. 7), are stacked on the IC chip 80.

A capacitor C21, which is some of a plurality of capacitors C21 to C24 (e.g., smoothing capacitors), is disposed in an SC capacitance portion 902 on a main surface 91 of a module laminate 9. That is, the smoothing capacitor C21 does not overlap the IC chip 80 in a plan view in the thickness direction D0 of the module laminate 9.

In a plan view in the thickness direction D0 of the module laminate 9, the capacitor C11 stacked on the IC chip 80 overlaps the SC switch portion 102 of the IC chip 80 as illustrated in FIG. 9. In a plan view in the thickness direction D0 of the module laminate 9, the capacitor C11 stacked on the IC chip 80 does not overlap the SM switch portion 104 of the IC chip 80 as illustrated in FIG. 9.

The plurality of capacitors C21 to C24 of the switched-capacitor circuit 20 and the capacitors C13 to C16 among the capacitors C11 to C16 are disposed in the SC capacitance portion 902 (see FIG. 1) on the main surface 91 of the module laminate 9.

### (2) Effects

In the tracker module 100 according to Embodiment 2, the capacitors C11 and C12 are flying capacitors. The capacitors C11 and C12 overlap the IC chip 80 in a plan view in the thickness direction D0 of the module laminate 9. In general, the capacitance of the flying capacitors C11 to C16 is larger than the capacitance of the smoothing capacitors C21 to C24. Thus, some of the flying capacitors C11 to C16 are stacked on the IC chip 80, and thus the switched-capacitor circuit 20 is less likely to be affected by the resistance or the parasitic capacitance of the wiring portion, and it is possible to further reduce the deterioration in the output characteristics of the tracker module 100.

In the tracker module 100 according to Embodiment 2, the capacitor C21 is a smoothing capacitor. The capacitor C21 is disposed at the module laminate 9. The capacitor C21 does not overlap the IC chip 80 in a plan view in the thickness direction D0 of the module laminate 9. Thus, when it is difficult to stack all the smoothing capacitors C21 to C24 on the IC chip 80, the wiring portion of the switched-capacitor circuit 20 can be shortened.

In the tracker module 100 according to Embodiment 2, the IC chip 80 includes the SC switch portion 102 and the SM switch portion 104. The SC switch portion 102 includes switches S11, S12, S21, S22, S31, S32, S41, and S42 included in the switched-capacitor circuit 20. The SM switch portion 104 includes switches S51 to S54 included in a supply modulator 30. The capacitor C11 overlaps the SC switch portion 102 in a plan view in the thickness direction D0 of the module laminate 9.

As a result, in the switched-capacitor circuit 20, it is possible to reduce a wiring portion between any of the switches S11, S12, S21, S22, S31, S32, S41, and S42 and the capacitor C11. Thus, it is possible to reduce the resistance or parasitic capacitance in the wiring portion of the switched-capacitor circuit 20 and to reduce the deterioration in the output characteristics of the tracker module 100.

In the tracker module 100 according to Embodiment 2, the capacitor C11 does not overlap the SM switch portion 104 in a plan view in the thickness direction D0 of the module laminate 9. As a result, since a distance between the capacitor C11 and the supply modulator 30 is not too close, the parasitic capacitance between the switched-capacitor circuit 20 and the supply modulator 30 can be reduced.

### Embodiment 3

### (1) Configuration

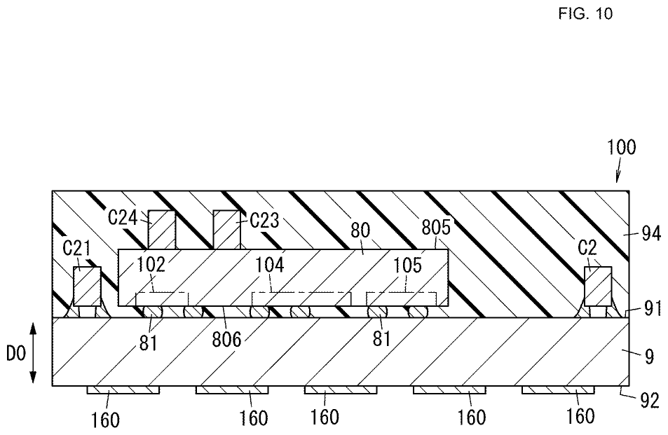

In a tracker module 100 according to Embodiment 3, as illustrated in FIG. 10, a plurality of capacitors are stacked on an IC chip 80. The plurality of capacitors stacked on the IC chip 80 are smoothing capacitors.

In the tracker module 100 according to Embodiment 3, capacitors C23 and C24, which are some of a plurality of capacitors C21 to C24 (e.g., smoothing capacitors) of a switched-capacitor circuit 20 (see FIG. 7), are stacked on the IC chip 80.

The capacitor C21, which is a portion of the plurality of capacitors C21 to C24 (e.g., smoothing capacitors), is disposed in an SC capacitance portion 902 on a main surface 91 of a module laminate 9. That is, the smoothing capacitor C21 does not overlap the IC chip 80 in a plan view in a thickness direction D0 of the module laminate 9.

In the plan view in the thickness direction D0 of the module laminate 9, the capacitor C24 stacked on the IC chip 80 overlaps an SC switch portion 102 of the IC chip 80 as illustrated in FIG. 10. In the plan view in the thickness direction D0 of the module laminate 9, the capacitor C24 stacked on the IC chip 80 does not overlap an SM switch portion 104 of the IC chip 80 as illustrated in FIG. 10.

A plurality of capacitors C11 to C16 of the switched-capacitor circuit 20 and the capacitors C23 and C24 among the capacitors C21 to C24 are disposed in the SC capacitance portion 902 (see FIG. 1) on the main surface 91 of the module laminate 9.

### (2) Effects

In the tracker module 100 according to Embodiment 3, the capacitors C23 and C24 are smoothing capacitors. The capacitors C23 and C24 overlap the IC chip 80 in the plan view in the thickness direction D0 of the module laminate 9. Thus, the stability of an output voltage of the switched-capacitor circuit 20 is improved, and the deterioration in the output characteristics of the tracker module 100 can further be reduced.

In the tracker module 100 according to Embodiment 3, the IC chip 80 includes the SC switch portion 102 and the SM switch portion 104. The SC switch portion 102 includes switches S11, S12, S21, S22, S31, S32, S41, and S42 included in the switched-capacitor circuit 20. The SM switch portion 104 includes switches S51 to S54 included in a supply modulator 30. The capacitor C24 overlaps the SC switch portion 102 in the plan view in the thickness direction D0 of the module laminate 9.

As a result, in the switched-capacitor circuit 20, it is possible to reduce a wiring portion between any of the switches S11, S12, S21, S22, S31, S32, S41, and S42 and the capacitor C24. Thus, it is possible to reduce the resistance or parasitic capacitance in the wiring portion of the switched-capacitor circuit 20 and to reduce the deterioration in the output characteristics of the tracker module 100.

In the tracker module 100 according to Embodiment 3, the capacitor C24 does not overlap the SM switch portion 104 in the plan view in the thickness direction D0 of the module laminate 9. As a result, since a distance between the capacitor C24 and the supply modulator 30 is not too close, it is possible to reduce the parasitic capacitance between the switched-capacitor circuit 20 and the supply modulator 30.

### Embodiment 4

### (1) Configuration

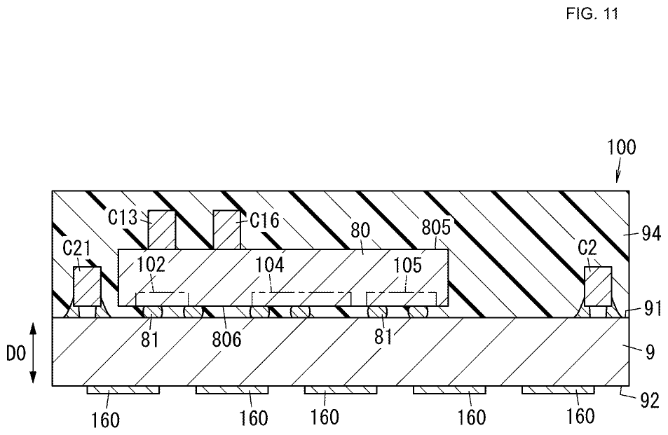

In a tracker module 100 according to Embodiment 4, as illustrated in FIG. 11, a capacitor C2 of a filter circuit 40 (see FIG. 7) is not stacked on an IC chip 80.

In the tracker module 100 according to Embodiment 4, capacitors C13 and C16, which are some of a plurality of capacitors C11 to C16 and C21 to C24 (see FIG. 7) of a switched-capacitor circuit 20 (see FIG. 7), are stacked on the IC chip 80.

The capacitor C21, which is a portion of the plurality of capacitors C21 to C24 (e.g., smoothing capacitors), is disposed in an SC capacitance portion 902 (see FIG. 1) on a main surface 91 of a module laminate 9. That is, the smoothing capacitor C21 does not overlap the IC chip 80 in the plan view in a thickness direction D0 of the module laminate 9.

In a plan view in the thickness direction D0 of the module laminate 9, the capacitor C24 stacked on the IC chip 80 overlaps an SC switch portion 102 of the IC chip 80 as illustrated in FIG. 10. In the plan view in the thickness direction D0 of the module laminate 9, the capacitor C24 stacked on the IC chip 80 does not overlap an SM switch portion 104 of the IC chip 80 as illustrated in FIG. 10.

A plurality of capacitors C11 to C16 of the switched-capacitor circuit 20 and the capacitors C23 and C24 among the capacitors C21 to C24 are disposed in the SC capacitance portion 902 (see FIG. 1) on the main surface 91 of the module laminate 9.

The plurality (two in FIG. 7) of capacitors C1 and C2 included in the filter circuit 40 (see FIG. 7) are disposed in a filter circuit portion 903 (see FIG. 1) on the main surface 91 of the module laminate 9. That is, the capacitors C1 and C2 of the filter circuit 40 do not overlap the IC chip 80 in the plan view in a thickness direction D0 of the module laminate 9.

### (2) Effects

The tracker module 100 according to Embodiment 4 includes the capacitors C1 and C2 included in the filter circuit 40. As illustrated in FIG. 7, the filter circuit 40 is connected between the supply modulator 30 and a power amplifier 2. The capacitors C1 and C2 are disposed at the module laminate 9. The capacitors C1 and C2 do not overlap the IC chip 80 in the plan view in the thickness direction D0 of the module laminate 9, whereby it is possible to obtain a sufficient distance between each of switches S11 to S44 included in the switched-capacitor circuit 20 and the capacitors C1 and C2 included in the filter circuit 40. Thus, it is possible to reduce the deterioration in filter performance of the filter circuit 40 due to an influence of the switched-capacitor circuit 20.

### Embodiment 5

### (1) Configuration

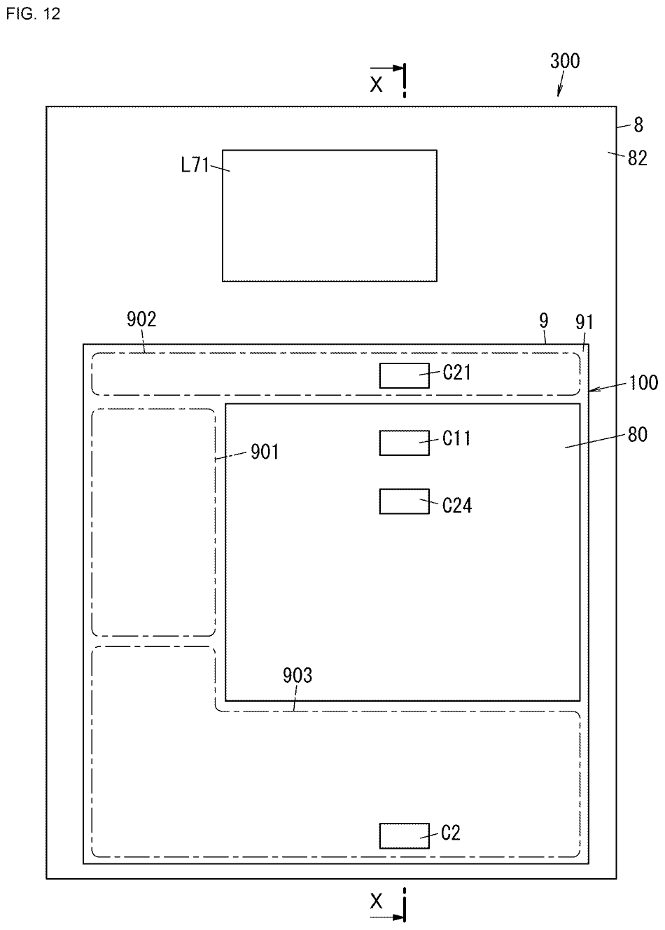

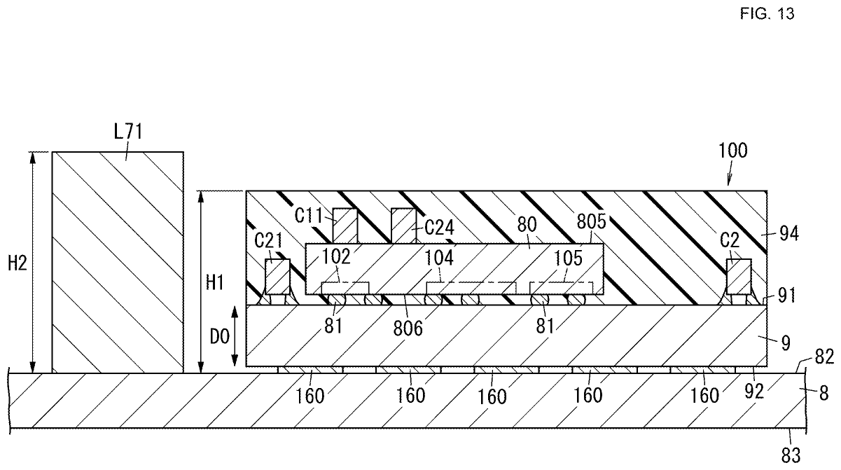

As illustrated in FIGS. 12 and 13, a power supply system 300 according to Embodiment 5 includes a tracker module 100 and a power inductor L71. The power supply system 300 further includes a second board 8 different from a module laminate 9 (e.g., a first board). The second board 8 is, for example, a motherboard of the communication device 7 (see FIG. 5) and is a printed wiring board.

The tracker module 100 and the power inductor L71 are disposed at the second board 8. The second board 8 has a third main surface 82 and a fourth main surface 83 that face each other in a thickness direction D0 of the module laminate 9. The tracker module 100 and the power inductor L71 are disposed on the third main surface 82 of the second board 8.

The power inductor L71 is used in a pre-regulator circuit 10 (see FIG. 7). Specifically, the power inductor L71 is used to step up and/or step down (step-up, step-down, or step-up/down) of a DC voltage in the pre-regulator circuit 10.

In the power supply system 300 according to Embodiment 5, as illustrated in FIG. 14, a height H2 of the power inductor L71 from the second board 8 is greater than a height H1 of the tracker module 100 from the second board 8.

For purposes of this disclosure, the phrase that “the height H1 of the tracker module 100 from the second board 8” means the maximum value of a distance between an outer peripheral surface of the tracker module 100 and the third main surface 82 of the second board 8, in a state where the tracker module 100 is mounted on the second board 8″. Moreover, the “height H1 of the tracker module 100 from the second board 8” is, for example, a distance from the main surface of the resin layer 94 opposite to the module laminate 9 to the third main surface 82 of the second board 8.

For purposes of this disclosure, the phrase that the “height H2 of the power inductor L71 from the second board 8” means the maximum value of a distance between an outer peripheral surface of the power inductor L71 and the third main surface 82 of the second board 8, in a state where the power inductor L71 is mounted on the second board 8. Moreover, the phrase that the “height H2 of the power inductor L71 from the second board 8” is, for example, a distance from the main surface of the power inductor L71 opposite to the second board 8 to the third main surface 82 of the second board 8.

In the power supply system 300 according to Embodiment 5, the height H2 of the power inductor L71 from the second board 8 is greater than the height H1 of the tracker module 100 from the second board 8. That is, the maximum value of the height of the power supply system 300 from the second board 8 depends on the height of the power inductor L71 and does not depend on the height of the tracker module 100. Thus, as compared to a comparative example in which the inductor is not stacked on the IC chip in the tracker module, in the power supply system 300 according to Embodiment 5, the maximum value of the height of the power supply system 300 from the second board 8 does not increase.

On the other hand, in the power supply system 300 according to Embodiment 5, among the capacitors C11 to C16 and C21 to C24 (see FIG. 7) included in the switched-capacitor circuit 20 (see FIG. 7), the capacitors C11 and C24 are stacked on the IC chip 80. Thus, since it is possible to reduce the number of capacitors disposed in the SC capacitance portion 902 on the main surface 91 of the module laminate 9, it is possible to decrease the area of the tracker module 100 in the plan view in the thickness direction D0 of the module laminate 9. Thus, in the power supply system 300 according to Embodiment 5, it is possible to reduce the size of the power supply system 300.

### (2) Effects

The power supply system 300 according to Embodiment 5 includes the second board 8, the tracker module 100, and the power inductor L71. The tracker module 100 is disposed at the second board 8. The power inductor L71 is disposed at the second board 8 and used in the pre-regulator circuit 10. The height H2 of the power inductor L71 from the second board 8 is greater than the height H1 of the tracker module 100 from the second board 8. As a result, in the power supply system 300 according to Embodiment 5, it is possible to decrease the area of the power supply system 300 in the plan view in the thickness direction D0 of the module laminate 9, without increasing the height of the tracker module 100 in the thickness direction D0 of the module laminate 9. Thus, it is possible to reduce the size of the power supply system 300.

### MODIFICATION EXAMPLES

Modification examples of the exemplary embodiments will be described below.

In the tracker modules 100 according to Embodiments 1 to 5, the two capacitors among the capacitors C11 to C16 and C21 to C24 included in the switched-capacitor circuit 20 are stacked on the IC chip 80, but one capacitor may be stacked on the IC chip 80, or three or more capacitors may be stacked on the IC chip 80 in an alternative aspect. For example, in the tracker module 100 according to Embodiment 2, the capacitors C11 to C13 may be stacked on the IC chip 80.

The tracker module 100 according to Embodiments 1 to 5 includes one IC chip 80, but the tracker module 100 may include a plurality of IC chips 80 in an alternative aspect. At this time, at least one of the switches S11 to S44 included in the switched-capacitor circuit 20 is included in any one of the plurality of IC chips 80. At least one of the switches S51 to S54 included in the supply modulator 30 is included in any one of the plurality of IC chips 80. At least one of the capacitors C11 to C16 and C21 to C24 included in the switched-capacitor circuit 20 is stacked on any one of the plurality of IC chips 80.

In the tracker module 100 according to Embodiments 1 to 5, the capacitor C2 included in the filter circuit 40 is not stacked on the IC chip 80, but similarly, the capacitor C1 and the inductors L1 and L2 included in the filter circuit 40 are also not stacked on the IC chip in an alternative aspect. As a result, a sufficient distance can be obtained between each of the switches S11 to S44 included in the switched-capacitor circuit 20 and the inductor L1 and L2 or the capacitor C1 included in the filter circuit 40. Thus, also in this case, it is possible to reduce the deterioration in filter performance of the filter circuit 40 due to an influence of the switched-capacitor circuit 20.

In the radio frequency systems 200 according to Embodiments 1 to 5, the IC chip 80 included in the tracker module 100 is disposed at the module laminate 9, but the IC chip 80 may be disposed at the second board 8 in an alternative aspect. In an exemplary aspect when the communication device 7 includes a motherboard different from the second board 8, the IC chip 80 may be disposed on the motherboard. In this case, at least one of the capacitors C11 to C16 and C21 to C24 included in the switched-capacitor circuit 20 is stacked on the IC chip 80. In other words, the IC chip 80 is located between at least one of the capacitors C11 to C16 and C21 to C24 included in the switched-capacitor circuit 20 and the second board 8 or the motherboard of the communication device 7.

### Additional Exemplary Aspects

The following aspects are disclosed in the present specification.

A tracker module (100) according to a first aspect includes a board (9), an IC chip (80), and at least one capacitor (C11 to C24) included in a switched-capacitor circuit (20). The IC chip (80) is disposed at the board (9). The switched-capacitor circuit (20) is configured to generate a plurality of discrete voltages based on an input voltage. The IC chip (80) includes at least one switch (S11 to S44) included in the switched-capacitor circuit (20) and at least one switch (S51 to S54) included in a supply modulator (30). The supply modulator (30) is configured to selectively output at least one of the plurality of discrete voltages to a power amplifier (2). The at least one capacitor (C11 to C24) is stacked on the IC chip (80).

According to the tracker module (100) according to the above aspect, in the switched-capacitor circuit (20), a wiring portion between the at least one switch (S11 to S44) and the at least one capacitor (C11 to C24) can be shortened. Thus, it is possible to reduce the deterioration in the output characteristics of the tracker module (100). Since at least one capacitor (C11 to C24) is stacked on the IC chip (80), it is possible to reduce the board (9) and reduce the size of the tracker module (100).

A tracker module (100) according to a second aspect includes a board (9), an IC chip (80), and at least one capacitor (C11 to C24) included in a switched-capacitor circuit (20). The IC chip (80) is disposed at the board (9). The switched-capacitor circuit (20) is configured to generate a plurality of discrete voltages based on an input voltage. The IC chip (80) includes at least one switch (S11 to S44) included in the switched-capacitor circuit (20) and at least one switch (S51 to S54) included in a supply modulator (30). The supply modulator (30) is configured to selectively output at least one of the plurality of discrete voltages to a power amplifier. The IC chip (80) is located between the at least one capacitor (C11 to C24) and the board (9).

According to the tracker module (100) according to the above aspect, in the switched-capacitor circuit (20), a wiring portion between the at least one switch (S11 to S44) and the at least one capacitor (C11 to C24) can be shortened. Thus, it is possible to reduce the deterioration in the output characteristics of the tracker module (100). Since at least one capacitor (C11 to C24) is stacked on the IC chip (80), it is possible to reduce the board (9) and reduce the size of the tracker module (100).

In a tracker module (100) according to a third aspect, in the first or second aspect, the IC chip (80) includes a first switch portion (102) and a second switch portion (104). The first switch portion (102) includes at least one switch (S11 to S44) included in the switched-capacitor circuit (20). The second switch portion (104) includes at least one switch (S51 to S54) included in the supply modulator (30), and is different from the first switch portion (102). The at least one capacitor (C11 to C24) overlaps the first switch portion (102) in the plan view in the thickness direction (D0) of the board (9).

According to the tracker module (100) according to the above aspect, in the switched-capacitor circuit (20), a wiring portion between the at least one switch (S11 to S44) and the at least one capacitor (C11 to C24) can be shortened. Thus, it is possible to reduce the deterioration in the output characteristics of the tracker module (100).

In a tracker module (100) according to a fourth aspect, in the third aspect, in the plan view in the thickness direction (D0) of the board (9), the second switch portion (104) does not overlap the at least one capacitor (C11 to C24).

According to the tracker module (100) according to the above aspect, a sufficient distance can be obtained between the capacitor (C11 to C24) included in the switched-capacitor circuit (20) and at least one switch (S51 to S54) included in the supply modulator (30). Thus, it is possible to reduce the deterioration in the output characteristics of the tracker module (100) due to the parasitic capacitance between the switched-capacitor circuit (20) and the supply modulator (30), and the like.

In a tracker module (100) according to a fifth aspect, in any one of the first to fourth aspects, the at least one capacitor (C11 to C24) includes at least one flying capacitor (C11 to C16). At least one flying capacitor (C11 to C16) overlaps the IC chip (80) in the plan view in the thickness direction (D0) of the board (9).

According to the tracker module (100) according to the above aspect, a wiring portion between the at least one flying capacitor (C11 to C16) and the at least one switch (S11 to S44) can be shortened. Thus, it is possible to further reduce the degree of the deterioration in the output characteristics of the tracker module (100).

A tracker module (100) according to a sixth aspect, in the fifth aspect, further includes at least one smoothing capacitor (C21 to C24). The at least one smoothing capacitor (C21 to C24) is included in the switched-capacitor circuit (20). The at least one smoothing capacitor (C21 to C24) is disposed at the board (9). The at least one smoothing capacitor (C21 to C24) does not overlap the IC chip (80) in the plan view in the thickness direction (D0) of the board (9).

According to the tracker module (100) of the above exemplary aspect, even when it is difficult to stack both the at least one flying capacitor (C11 to C16) and the at least one smoothing capacitor (C21 to C24) on the IC chip (80), it is possible to reduce the deterioration in the output characteristics of the tracker module (100) and to reduce the size of the tracker module (100).

A tracker module (100) according to a seventh aspect, in the sixth aspect, further includes at least one capacitor (C1 and C2) or inductor (L0 to L2) included in the filter circuit (40). The filter circuit (40) is connected between the supply modulator (30) and the power amplifier (2). The at least one capacitor (C1 and C2) or inductor (L0 to L2) included in the filter circuit (40) is disposed at the board (9), and does not overlap the IC chip (80) in the plan view in the thickness direction (D0) of the board (9).

According to the tracker module (100) according to the above aspect, a sufficient distance can be obtained between the at least one switch (S11 to S44) included in the switched-capacitor circuit (20) and the at least one capacitor (C1 and C2) or inductor (L0 to L2) included in the filter circuit (40). Thus, it is possible to reduce the deterioration in filter performance of the filter circuit (40) due to an influence of the switched-capacitor circuit (20).

A tracker module (100) according to an eighth aspect, in the fifth aspect, further includes at least one capacitor (C1 and C2) or inductor (L0 to L2) included in the filter circuit (40). The filter circuit (40) is connected between the supply modulator (30) and the power amplifier (2). The at least one capacitor (C1 and C2) or inductor (L0 to L2) included in the filter circuit (40) is disposed at the board (9), and does not overlap the IC chip (80) in the plan view in the thickness direction (D0) of the board (9).

According to the tracker module (100) according to the above aspect, a sufficient distance can be obtained between the at least one switch (S11 to S44) included in the switched-capacitor circuit (20) and the at least one capacitor (C1 and C2) or inductor (L0 to L2) included in the filter circuit (40). Thus, it is possible to reduce the deterioration in filter performance of the filter circuit (40) due to an influence of the switched-capacitor circuit (20).

In a tracker module (100) according to a ninth aspect, in any one of the first to fourth aspects, the at least one capacitor (C11 to C24) includes at least one smoothing capacitor (C21 to C24). The at least one smoothing capacitor (C21 to C24) overlaps the IC chip (80) in the plan view in the thickness direction (D0) of the board (9).

According to the tracker module (100) according to the above aspect, a wiring portion between the at least one smoothing capacitor (C21 to C24) and the at least one switch (S11 to S44) can be shortened. Thus, the stability of an output voltage of the switched-capacitor circuit (20) is improved, and it is possible to further reduce the degree of the deterioration in the output characteristics of the tracker module (100).

A tracker module (100) according to a tenth aspect, in the ninth aspect, further includes at least one capacitor (C1 and C2) or inductor (L0 to L2) included in the filter circuit (40). The filter circuit (40) is connected between the supply modulator (30) and the power amplifier (2). The at least one capacitor (C1 and C2) or inductor (L0 to L2) included in the filter circuit (40) is disposed at the board (9), and does not overlap the IC chip (80) in the plan view in the thickness direction (D0) of the board (9).

According to the tracker module (100) according to the above aspect, a sufficient distance can be obtained between the at least one switch (S11 to S44) included in the switched-capacitor circuit (20) and the at least one capacitor (C1 and C2) or inductor (L0 to L2) included in the filter circuit (40). Thus, it is possible to reduce the deterioration in filter performance of the filter circuit (40) due to an influence of the switched-capacitor circuit (20).

A power supply system (300) according to an eleventh aspect includes the tracker module (100) according to any one of the first to tenth aspects, a power inductor (L71), and a second board (8) when the board (9) is set as a first board (9). The power inductor (L71) is used in a pre-regulator circuit (10). The pre-regulator circuit (10) is configured to convert a DC voltage into an input voltage. The tracker module (100) and the power inductor (L71) are disposed at the second board (8). A height (H2) of the power inductor (L71) from the second board (8) is greater than a height (H1) of the tracker module (100) from the second board (8).

According to the power supply system (300) according to the above aspect, it is possible to decrease an area of the power supply system (300) in the plan view in a thickness direction (D0) of the first board (9) without increasing the height (H1) of the tracker module (100). Thus, it is possible to reduce the size of the power supply system (300).

A radio frequency system (200) according to a twelfth aspect includes the tracker module (100) according to any one of the first to eleventh aspects, and a power amplifier (2) connected to the tracker module (100).

According to the radio frequency system (200) according to the above aspect, in the switched-capacitor circuit (20), a wiring portion between the at least one switch (S11 to S44) and the at least one capacitor (C11 to C24) can be shortened. Thus, it is possible to reduce the deterioration in the output characteristics of the tracker module (100). Since at least one capacitor (C11 to C24) is stacked on the IC chip (80), it is possible to reduce the board (9) and reduce the size of the tracker module (100).

A communication device (7) according to a thirteenth aspect includes the radio frequency system (200) according to the twelfth aspect and a signal processing circuit (5) connected to the radio frequency system (200).

According to the communication device (7) according to the above aspect, in the switched-capacitor circuit (20), a wiring portion between the at least one switch (S11 to S44) and the at least one capacitor (C11 to C24) can be shortened. Thus, it is possible to reduce the deterioration in the output characteristics of the tracker module (100). Since at least one capacitor (C11 to C24) is stacked on the IC chip (80), it is possible to reduce the board (9) and reduce the size of the tracker module (100).

An IC chip (80) according to a fourteenth aspect is connected to at least one capacitor (C11 to C24) included in a switched-capacitor circuit (20). The switched-capacitor circuit (20) is configured to generate a plurality of discrete voltages based on an input voltage. The IC chip (80) includes at least one switch included in the switched-capacitor circuit (20) and at least one switch included in a supply modulator (30). The supply modulator (30) is configured to selectively output at least one of the plurality of discrete voltages to a power amplifier. The at least one capacitor (C11 to C24) is stacked on the IC chip (80).

According to the IC chip (80) according to the above aspect, in the switched-capacitor circuit (20), a wiring portion between the at least one switch (S11 to S44) and the at least one capacitor (C11 to C24) can be shortened. Thus, it is possible to reduce the deterioration in the output characteristics of the tracker module (100) including the IC chip (80). Since at least one capacitor (C11 to C24) is stacked on the IC chip (80), it is possible to reduce the size of the tracker module (100).

An IC chip (80) according to a fifteenth aspect, in the fourteenth aspect, further includes a first switch portion (102) and a second switch portion (104). The first switch portion (102) includes at least one switch (S11 to S44) included in the switched-capacitor circuit (20). The second switch portion (104) includes at least one switch (S51 to S54) included in the supply modulator (30). The at least one capacitor (C11 to C24) overlaps the first switch portion (102) in the plan view in a thickness direction (D0) of the IC chip (80).

According to the IC chip (80) according to the above aspect, in the switched-capacitor circuit (20), a wiring portion between the at least one switch (S11 to S44) and the at least one capacitor (C11 to C24) can be shortened. Thus, it is possible to reduce the deterioration in the output characteristics of the tracker module (100).

In a tracker module (100) according to a sixteenth aspect, in the fifteenth aspect, in the plan view in the thickness direction (D0) of the IC chip (80), the second switch portion (104) does not overlap the at least one capacitor (C11 to C24).

According to the IC chip (80) according to the above aspect, a sufficient distance can be obtained between the capacitor (C11 to C24) included in the switched-capacitor circuit (20) and at least one switch (S51 to S54) included in the supply modulator (30). Thus, it is possible to reduce the deterioration in the output characteristics of the tracker module (100) due to the parasitic capacitance between the switched-capacitor circuit (20) and the supply modulator (30), and the like.

In an IC chip (80) according to a seventeenth aspect, in any one of the fourteenth to sixteenth aspects, the at least one capacitor (C11 to C24) includes at least one flying capacitor (C11 to C16). The at least one flying capacitor (C11 to C16) overlaps the IC chip (80) in the plan view in the thickness direction (D0) of the IC chip (80).

According to the IC chip (80) according to the above aspect, a wiring portion between the at least one flying capacitor (C11 to C16) and the at least one switch (S11 to S44) can be shortened. Thus, it is possible to further reduce the degree of the deterioration in the output characteristics of the tracker module (100).

In an IC chip (80) according to an eighteenth aspect, in the seventeenth aspect, at least one smoothing capacitor (C21 to C24) is included in the switched-capacitor circuit (20). The at least one smoothing capacitor (C21 to C24) does not overlap the IC chip (80) in the plan view in the thickness direction (D0) of the IC chip (80).

According to the IC chip (80) of the above exemplary aspect, even when it is difficult to stack both the at least one flying capacitor (C11 to C16) and the at least one smoothing capacitor (C21 to C24) on the IC chip (80), it is possible to reduce the deterioration in the output characteristics of the tracker module (100) and to reduce the size of the tracker module (100).

In an IC chip (80) according to a nineteenth aspect, in any one of the fourteenth to sixteenth aspects, the at least one capacitor (C11 to C24) includes at least one smoothing capacitor (C21 to C24). The at least one smoothing capacitor (C21 to C24) overlaps the IC chip (80) in the plan view in the thickness direction (D0) of the IC chip (80).

According to the IC chip (80) according to the above aspect, a wiring portion between the at least one smoothing capacitor (C21 to C24) and the at least one switch (S11 to S44) can be shortened. Thus, the stability of an output voltage of the switched-capacitor circuit (20) is improved, and it is possible to further reduce the degree of the deterioration in the output characteristics of the tracker module (100).

In an IC chip (80) according to a twentieth aspect, in any one of the seventeenth to nineteenth aspects, at least one capacitor (C1 and C2) or inductor (L0 to L2) included in the filter circuit (40) does not overlap the IC chip (80) in the plan view in the thickness direction (D0) of the IC chip (80). The filter circuit (40) is connected between the supply modulator (30) and the power amplifier (2).

According to the IC chip (80) according to the above aspect, a sufficient distance can be obtained between the at least one switch (S11 to S44) included in the switched-capacitor circuit (20) and the at least one capacitor (C1 and C2) or inductor (L0 to L2) included in the filter circuit (40). Thus, it is possible to reduce the deterioration in filter performance of the filter circuit (40) due to an influence of the switched-capacitor circuit (20).

What is claimed:

1. A tracker module comprising:
a board;
at least one capacitor included in a switched-capacitor circuit that is configured to generate a plurality of discrete voltages based on an input voltage; and
an IC chip disposed at the board and including:
at least one switch included in the switched-capacitor circuit, and
at least one switch included in a supply modulator that is configured to selectively output at least one of the plurality of discrete voltages to a power amplifier,
wherein the at least one capacitor is stacked on the IC chip.

2. The tracker module according to claim 1, wherein the IC chip includes:
a first switch portion that includes the at least one switch included in the switched-capacitor circuit, and
a second switch portion that includes the at least one switch included in the supply modulator, and
wherein the at least one capacitor overlaps the first switch portion in a plan view in a thickness direction of the board.

3. The tracker module according to claim 2, wherein the second switch portion does not overlap the at least one capacitor in the plan view in the thickness direction of the board.

4. The tracker module according to claim 1, wherein the at least one capacitor includes at least one flying capacitor that overlaps the IC chip in a plan view in a thickness direction of the board.

5. The tracker module according to claim 4, further comprising:
at least one smoothing capacitor included in the switched-capacitor circuit,
wherein the at least one smoothing capacitor is disposed at the board and does not overlap the IC chip in the plan view in the thickness direction of the board.

6. The tracker module according to claim 5, further comprising:
a filter circuit that includes at least one of a capacitor and an inductor and that is connected between the supply modulator and the power amplifier,
wherein the at least one of the capacitor and the inductor is disposed at the board and does not overlap the IC chip in the plan view in the thickness direction of the board.

7. The tracker module according to claim 4, further comprising:
a filter circuit that includes at least one of a capacitor and an inductor and that is connected between the supply modulator and the power amplifier,
wherein the at least one of the capacitor and the inductor is disposed at the board and does not overlap the IC chip in the plan view in the thickness direction of the board.

8. The tracker module according to claim 1, wherein the at least one capacitor includes at least one smoothing capacitor that overlaps the IC chip in a plan view in a thickness direction of the board.

9. The tracker module according to claim 8, further comprising:
a filter circuit that includes at least one of a capacitor and an inductor and that is connected between the supply modulator and the power amplifier,
wherein the at least one of the capacitor and the inductor is disposed at the board and does not overlap the IC chip in the plan view in the thickness direction of the board.

10. A power supply system comprising:
the tracker module according to claim 1;
a power inductor in a pre-regulator circuit that is configured to convert a DC voltage into the input voltage; and
an additional board at which the tracker module and the power inductor are disposed,
wherein a height of the power inductor from the additional board is greater than a height of the tracker module from the additional board.

11. A radio frequency system comprising:
the tracker module according to claim 1; and
the power amplifier connected to the tracker module.

12. A communication device comprising:
the radio frequency system according to claim 11; and
a signal processing circuit connected to the radio frequency system.

13. A tracker module comprising:
a board;
at least one capacitor included in a switched-capacitor circuit that is configured to generate a plurality of discrete voltages based on an input voltage; and
an IC chip located between the at least one capacitor and the board, the IC chip including:
at least one switch included in the switched-capacitor circuit, and
at least one switch included in a supply modulator that is configured to selectively output at least one of the plurality of discrete voltages to a power amplifier.

14. An IC chip that is connected to at least one capacitor included in a switched-capacitor circuit configured to generate a plurality of discrete voltages based on an input voltage, the IC chip comprising:
at least one switch included in the switched-capacitor circuit; and
at least one switch included in a supply modulator that is configured to selectively output at least one of the plurality of discrete voltages to a power amplifier,
wherein the at least one capacitor is stacked on the IC chip.

15. The IC chip according to claim 14, further comprising:
a first switch portion that includes the at least one switch included in the switched-capacitor circuit; and
a second switch portion that includes the at least one switch included in the supply modulator,
wherein the at least one capacitor overlaps the first switch portion in a plan view in a thickness direction of the IC chip.

16. The IC chip according to claim 15, wherein the second switch portion does not overlap the at least one capacitor in the plan view in the thickness direction of the IC chip.

17. The IC chip according to claim 14, wherein the at least one capacitor includes at least one flying capacitor that overlaps the IC chip in a plan view in a thickness direction of the IC chip.

18. The IC chip according to claim 17, further comprising at least one smoothing capacitor included in the switched-capacitor circuit and that does not overlap the IC chip in the plan view in the thickness direction of the IC chip.

19. The IC chip according to claim 14, wherein the at least one capacitor includes at least one smoothing capacitor that overlaps the IC chip in a plan view in a thickness direction of the IC chip.

20. The IC chip according to claim 17, wherein at least one capacitor or inductor included in a filter circuit connected between the supply modulator and the power amplifier does not overlap the IC chip in the plan view in the thickness direction of the IC chip.
